(19) United States
(12) Patent Application Publication
(10) Pub. No.: US 2024/0244754 A1
(43) Pub. Date: Jul. 18, 2024

(54) Circuit Device

(71) Applicant: Mitsubishi Electric Corporation, Chiyoda-ku, Tokyo (JP)

(72) Inventors: Yoshimichi SAITO, Chiyoda-ku, Tokyo (JP); Yoshikazu TSUNODA, Chiyoda-ku, Tokyo (JP); Kenta FUJII, Chiyoda-ku, Tokyo (JP); Takashi KUMAGAI, Chiyoda-ku, Tokyo (JP); Tomohito FUKUDA, Chiyoda-ku, Tokyo (JP); Yuji SHIRAKATA, Chiyoda-ku, Tokyo (JP)

(73) Assignee: Mitsubishi Electric Corporation, Chiyoda-ku, Tokyo (JP)

(21) Appl. No.: 18/559,943

(22) PCT Filed: Jun. 14, 2022
(86) PCT No.: PCT/JP2022/023770

§ 371 Date: Nov. 9, 2023

(30) Foreign Application Priority Data
Jun. 22, 2021 (JP) 2021-103423

(51) Int. Cl. H05K 1/18; H05K 3/00

(52) U.S. Cl. CPC H05K 1/184; H05K 3/0085; H05K 2201/066; H05K 2201/095; H05K 2201/10015; H05K 2201/10409; H05K 2203/1147

(57) ABSTRACT

A circuit device includes: a heat sink having an upper surface orthogonal to a first direction; a plurality of first partition plates attached to the upper surface and extending in a second direction orthogonal to the first direction; a plurality of second partition plates attached to the upper surface and extending in a third direction orthogonal to the first direction and the second direction; a circuit component; a substrate electrically connected to the circuit component; and a first heat transfer member. The circuit component is housed in a space surrounded by two adjacent first partition plates, two adjacent second partition plates, and the upper surface. The first heat transfer member is disposed between the first partition plate and the circuit component.

### TECHNICAL FIELD

The present disclosure relates to a circuit device.

### BACKGROUND ART

Japanese Patent Laying-Open No. 2006-12948 (PTL 1) describes a circuit device. The circuit device described in PTL 1 has a heat sink, a plurality of attachment members, and a plurality of capacitors. The plurality of attachment members are attached side by side to an upper surface of the heat sink. A side surface of the capacitor is in thermal contact with the attachment member.

Japanese Patent Laying-Open No. 2016-66666 (PTL 2) describes a circuit device. The circuit device described in PTL 2 has a heat sink, a plurality of capacitors, and a lid body. The capacitor is disposed facing an upper surface of the heat sink with an interval therebetween. The lid body is attached to the heat sink so as to cover the capacitor.

### CITATION LIST

### Patent Literature

PTL 1: Japanese Patent Laying-Open No. 2006-12948
PTL 2: Japanese Patent Laying-Open No. 2016-66666

### SUMMARY OF INVENTION

### Technical Problem

In the circuit device described in PTL 1, a top surface of the capacitor is not in thermal contact with the heat sink. Therefore, the circuit device described in PTL 1 has room for improvement in heat dissipation performance.

In the circuit device described in PTL 2, heat generated from the capacitor is transmitted to the heat sink through the lid body and an opening portion of the lid body.

A heat transfer path from a capacitor (a capacitor at a center) away from the opening portion of the lid body is longer than a heat transfer path from a capacitor (a capacitor at an end) near the opening portion of the lid body. Therefore, in the circuit device described in PTL 2, a temperature gradient occurs between the capacitor at the center and the capacitor at the end.

The present disclosure has been made in view of the above-described problem of the related art. More specifically, the present disclosure provides a circuit device capable of improving heat dissipation performance and reducing a temperature gradient between a circuit component at a center and a circuit component at an end.

### Solution to Problem

A circuit device of the present disclosure includes: a heat sink having an upper surface orthogonal to a first direction; a plurality of first partition plates attached to the upper surface and extending in a second direction orthogonal to the first direction; a plurality of second partition plates attached to the upper surface and extending in a third direction orthogonal to the first direction and the second direction; a circuit component; a substrate electrically connected to the circuit component; and a first heat transfer member. The circuit component is housed in a space surrounded by two adjacent first partition plates, two adjacent second partition plates, and the upper surface. The first heat transfer member is disposed between the first partition plate and the circuit component.

### Advantageous Effects of Invention

According to the circuit device of the present disclosure, it is possible to improve heat dissipation performance and reduce a temperature gradient between a circuit component at a center and a circuit component at an end.

### BRIEF DESCRIPTION OF DRAWINGS

FIG. 1 is a circuit diagram of a circuit device 100.

FIG. 2 is an exploded perspective view of circuit device 100.

FIG. 3 is a plan view of a first partition plate 41.

FIG. 4 is a plan view of a second partition plate 42.

FIG. 5 is a plan view of a third partition plate 43.

FIG. 6 is a cross-sectional view taken along line VI-VI in FIG. 2.

FIG. 7 is a process flowchart illustrating an assembly method for circuit device 100.

FIG. 8 is a cross-sectional view of a circuit device 100A.

FIG. 9 is a cross-sectional view of a circuit device 100B.

FIG. 10 is a cross-sectional view of a circuit device 100C.

FIG. 11 is a top view of third partition plate 43 included in a circuit device 100D.

FIG. 12 is a cross-sectional view of a circuit device 200.

FIG. 13 is a perspective view of a first partition plate 41 included in circuit device 200.

FIG. 14 is a perspective view of a second partition plate 42 included in circuit device 200.

FIG. 15 is a perspective view of a third partition plate 43 included in circuit device 200.

FIG. 16 is a process flowchart illustrating an assembly method for circuit device 200.

FIG. 17 is a cross-sectional view of a circuit device 200A.

FIG. 18 is a plan view of first partition plate 41 included in circuit device 200A.

FIG. 19 is a plan view of second partition plate 42 included in circuit device 200A.

FIG. 20 is a plan view of third partition plate 43 included in circuit device 200A.

FIG. 21 is a cross-sectional view of a circuit device 200B.

FIG. 22 is a circuit diagram of circuit device 200B.

FIG. 23 is a cross-sectional view of a circuit device 300.

FIG. 24 is a perspective view of a first partition plate 41 included in circuit device 300.

FIG. 25 is a perspective view of a second partition plate 42 included in circuit device 300.

FIG. 26 is a perspective view of a third partition plate 43 included in circuit device 300.

FIG. 27 is a process flowchart illustrating an assembly method for circuit device 300.

FIG. 28 is an exploded perspective view of a circuit device 400.

FIG. 29 is a cross-sectional view taken along line XXIX-XXIX in FIG. 28.

FIG. 30 is a perspective view of a third partition plate 43 included in circuit device 400.

FIG. 31 is a cross-sectional view of a circuit device 400A.

FIG. 32 is a perspective view of third partition plate 43 included in circuit device 400A.

FIG. 33 is an exploded perspective view of a circuit device 500.

FIG. 34 is a cross-sectional view taken along line XXXIV-XXXIV in FIG. 33.

FIG. 35 is a perspective view of a first partition plate 41 included in circuit device 500.

FIG. 36 is a perspective view of a second partition plate 42 included in circuit device 500.

FIG. 37 is a perspective view of a third partition plate 43 included in circuit device 500.

FIG. 38 is an exploded perspective view of a circuit device 600.

FIG. 39 is a cross-sectional view taken along line XXXIX-XXXIX in FIG. 38.

FIG. 40 is a perspective view of a third partition plate 43 included in circuit device 600.

FIG. 41 is an exploded perspective view of a circuit device 700.

FIG. 42 is a plan view of a first partition plate 41 included in circuit device 700.

FIG. 43 is a plan view of a second partition plate 42 included in circuit device 700.

FIG. 44 is a plan view of a third partition plate 43 included in circuit device 700.

FIG. 45 is an exploded perspective view of circuit device 700A.

FIG. 46 is a plan view of first partition plate 41 included in circuit device 700A.

FIG. 47 is a plan view of second partition plate 42 included in circuit device 700A.

FIG. 48 is a plan view of third partition plate 43 included in circuit device 700A.

FIG. 49 is an exploded perspective view of a circuit device 700B.

### DESCRIPTION OF EMBODIMENTS

Details of embodiments of the present disclosure will be described with reference to the drawings. In the following drawings, the same or corresponding parts are denoted by the same reference numerals, and redundant descriptions will not be repeated.

### First Embodiment

A circuit device (hereinafter referred to as “circuit device 100”) according to a first embodiment will be described.

### (Configuration of Circuit Device 100)

Hereinafter, a configuration of circuit device 100 will be described.

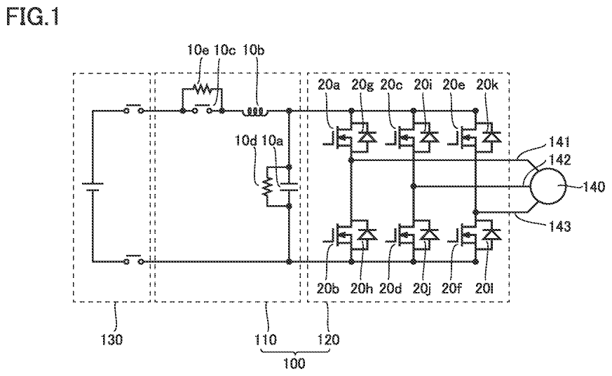

Circuit device 100 is, for example, a power conversion device. Although circuit device 100 is not limited to the power conversion device, the power conversion device will be described below as an example of circuit device 100. FIG. 1 is a circuit diagram of circuit device 100. As illustrated in FIG. 1, circuit device 100 has a peripheral circuit 110 and a switching circuit 120.

Peripheral circuit 110 has a plurality of circuit components 10. In the example illustrated in FIG. 1, the plurality of circuit components 10 are a capacitor 10a, an inductor 10b, a contactor 10c, a discharge resistor 10d, and a charge resistor 10e. Capacitor 10a, inductor 10b, and contactor 10c are connected in series. Inductor 10b is disposed between capacitor 10a and contactor 10c. Discharge resistor 10d and charge resistor 10e are connected in parallel to capacitor 10a and contactor 10c, respectively. Peripheral circuit 110 is connected to a DC supply circuit 130.

Switching circuit 120 is, for example, a three-phase inverter circuit. Switching circuit 120 has a plurality of circuit components 20. In the example illustrated in FIG. 1, the plurality of circuit components 20 are transistors 20a to 20f and diodes 20g to 20l.

A drain of transistor 20a is electrically connected to one electrode of capacitor 10a. A source of transistor 20a is electrically connected to a drain of transistor 20b. A source of transistor 20b is electrically connected to another electrode of capacitor 10a.

An anode of diode 20g is electrically connected to the source of transistor 20a. A cathode of diode 20g is electrically connected to the drain of transistor 20a. An anode of diode 20h is electrically connected to the source of transistor 20b. A cathode of diode 20h is electrically connected to the drain of transistor 20b.

Note that transistor 20c, transistor 20d, diode 20i, and diode 20j are connected similarly to transistor 20a, transistor 20b, diode 20g, and diode 20h, respectively. Further, transistor 20e, transistor 20f, diode 20k, and diode 20l are connected similarly to transistor 20a, transistor 20b, diode 20g, and diode 20h, respectively. Although not illustrated, gates of transistors 20a to 20f are connected to a control circuit.

Switching circuit 120 is connected to a motor 140. Motor 140 is, for example, a three-phase motor. Motor 140 has an input line 141, an input line 142, and an input line 143. Input line 141 is electrically connected to the source of transistor 20a and the drain of transistor 20b. Input line 142 is electrically connected to the source of transistor 20c and the drain of transistor 20d. Input line 143 is electrically connected to the source of transistor 20e and the drain of transistor 20f.

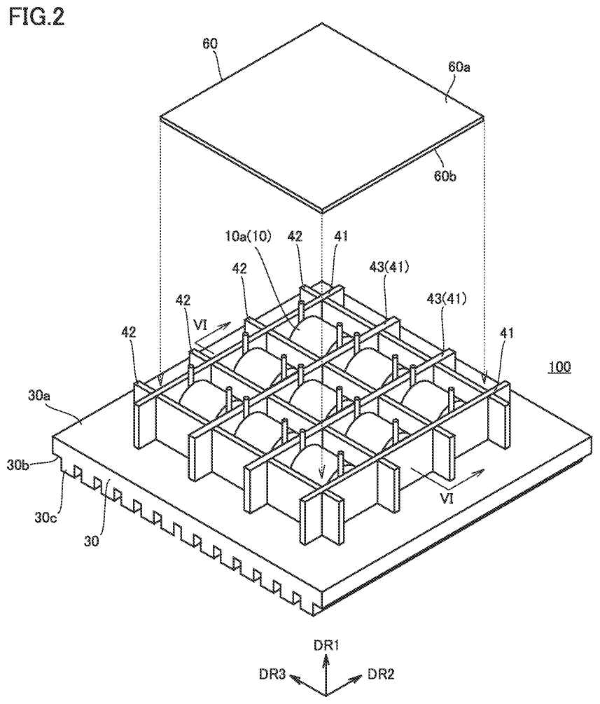

FIG. 2 is an exploded perspective view of circuit device 100. As illustrated in FIG. 2, circuit device 100 has a heat sink 30, a plurality of first partition plates 41, and a plurality of second partition plates 42.

Heat sink 30 has an upper surface 30a and a lower surface 30b. Upper surface 30a is orthogonal to a first direction DR1. Lower surface 30b is a surface opposite to upper surface 30a. A direction orthogonal to first direction DR1 is defined as a second direction DR2. A direction orthogonal to first direction DR1 and second direction DR2 is defined as a third direction DR3.

A plurality of fins 30c are formed on lower surface 30b. Fins 30c extend, for example, in second direction DR2. The plurality of fins 30c are disposed at intervals in third direction DR3. Heat sink 30 is formed by, for example, a metal material having an excellent thermal conductivity, such as copper (copper alloy) or aluminum (aluminum alloy). Heat sink 30 is formed by extrusion processing, for example. The extrusion processing is performed, for example, along an extending direction (second direction DR2) of fin 30c.

First partition plate 41 is attached to upper surface 30a. First partition plate 41 extends in second direction DR2. The plurality of first partition plates 41 are disposed at intervals in third direction DR3. For first partition plate 41, for example, a rolled material formed by a metal material having an excellent thermal conductivity such as copper (copper alloy) or aluminum (aluminum alloy) is used.

Second partition plate 42 is attached to upper surface 30a. Second partition plate 42 extends in third direction DR3. The plurality of second partition plates 42 are disposed at intervals in second direction DR2. From another point of view of this fact, first partition plate 41 and second partition plate 42 are attached to upper surface 30a in a parallel-cross pattern. For second partition plate 42, for example, a rolled material formed by a metal material having an excellent thermal conductivity such as copper (copper alloy) or aluminum (aluminum alloy) is used.

First partition plate 41 disposed at a position other than both ends in third direction DR3 is referred to as a third partition plate 43. The number of third partition plates 43 is at least one. In the example illustrated in FIG. 2, the number of third partition plates 43 is two.

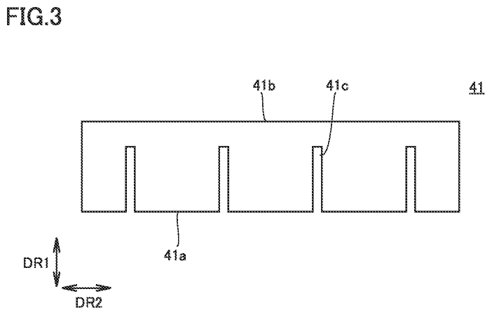

FIG. 3 is a plan view of first partition plate 41. As illustrated in FIG. 3, first partition plate 41 has a first end 41a and a second end 41b. First end 41a is an end on upper surface 30a side. Second end 41b is an end on a side opposite to first end 41a. A plurality of first insertion ports 41c are formed in first partition plate 41 at intervals in second direction DR2. First insertion ports 41c extend from first end 41a toward second end 41b. First insertion ports 41c penetrate first partition plate 41 along a thickness direction.

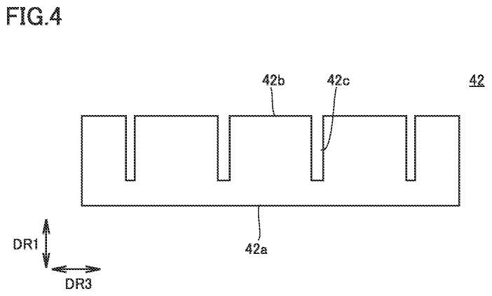

FIG. 4 is a plan view of second partition plate 42. As illustrated in FIG. 4, second partition plate 42 has a third end 42a and a fourth end 42b. Third end 42a is an end on upper surface 30a side. Fourth end 42b is an end on a side opposite to third end 42a. Second partition plate 42 has a plurality of second insertion ports 42c formed at intervals in third direction DR3. Second insertion ports 42c extend from fourth end 42b toward third end 42a. Second insertion ports 42c penetrate second partition plate 42 along a thickness direction.

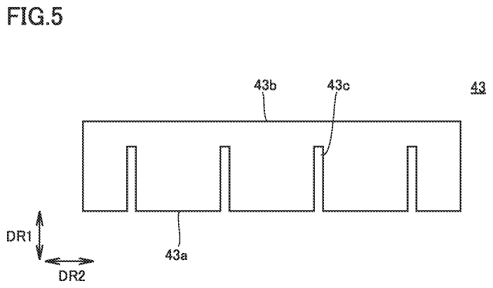

FIG. 5 is a plan view of third partition plate 43. As illustrated in FIG. 5, third partition plate 43 has a fifth end 43a and a sixth end 43b. Fifth end 43a is an end on upper surface 30a side. Sixth end 43b is an end on a side opposite to fifth end 43a. A plurality of third insertion ports 43c are formed in third partition plate 43 at intervals in second direction DR2. Third insertion ports 43c extend from fifth end 43a toward sixth end 43b. Third insertion ports 43c penetrate third partition plate 43 along a thickness direction.

Second insertion ports 42c are inserted into first insertion ports 41c and third insertion ports 43c. This prevents first partition plate 41 and third partition plate 43 from interfering with second partition plate 42.

A thickness of third partition plate 43 in third direction DR3 is preferably larger than a thickness of first partition plate 41 in third direction DR3. From another point of view of this fact, a contact area between third partition plate 43 and upper surface 30a is preferably larger than a contact area of first partition plate 41 between with upper surface 30a.

First partition plate 41, second partition plate 42, and third partition plate 43 can be manufactured by any method. First partition plate 41, second partition plate 42, and third partition plate 43 may be manufactured, for example, by performing punching processing on a plate-shaped member or by performing milling processing on a plate-shaped member. Further, first partition plate 41, second partition plate 42, and third partition plate 43 may be manufactured by extrusion molding.

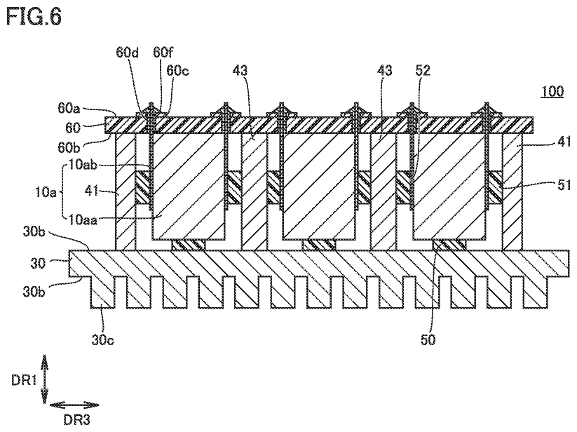

FIG. 6 is a cross-sectional view taken along line VI-VI in FIG. 2. As illustrated in FIG. 6, capacitor 10a (circuit component 10) is disposed in a space surrounded by two adjacent first partition plates 41 (first partition plate 41 and third partition plate 43 adjacent to each other or two adjacent third partition plates 43), two adjacent second partition plates 42, and upper surface 30a.

Circuit component 10 has a circuit component body and a lead wire. In a case where circuit component 10 is capacitor 10a, the circuit component body is a capacitor element body 10aa, and the lead wire is a lead wire 10ab. Lead wire 10ab is electrically connected to capacitor element body 10aa. Circuit device 100 further has an adhesive 50, a heat transfer member 51, a heat transfer member 52, and a substrate 60.

Adhesive 50 is disposed between atop surface of capacitor 10a and upper surface 30a. Adhesive 50 is formed by, for example, a resin material such as silicone resin, epoxy resin, or urethane resin. A thermally conductive filler may be mixed in adhesive 50 in order to improve a thermal conductivity. The thermally conductive filler is formed by, for example, a metal material or a ceramic material. Adhesive 50 may be formed by, for example, a material having a thermal conductivity of greater than or equal to 1 W/m·K and less than or equal to several 10 W/m·K.

Heat transfer member 51 is disposed between capacitor 10a and first partition plate 41. More specifically, heat transfer member 51 is disposed between first partition plate 41 and a surface of capacitor element body 10aa to which lead wire 10ab is attached, or between first partition plate 41 and lead wire 10ab. Heat transfer member 51 may be disposed both between first partition plate 41 and the surface of capacitor element body 10aa to which lead wire 10ab is attached, and between first partition plate 41 and lead wire 10ab.

Heat transfer member 52 is disposed between capacitor 10a and third partition plate 43. More specifically, heat transfer member 52 is disposed between third partition plate 43 and the surface of capacitor element body 10aa to which lead wire 10ab is attached, or between third partition plate 43 and lead wire 10ab. Heat transfer member 52 may be disposed between third partition plate 43 and the surface of capacitor element body 10aa to which lead wire 10ab is attached, and between third partition plate 43 and lead wire 10ab.

Heat transfer member 51 and heat transfer member 52 are formed by, for example, a resin material such as silicone resin, epoxy resin, or urethane resin. A thermally conductive filler may be mixed in heat transfer member 51 and heat transfer member 52 in order to improve a thermal conductivity. The thermally conductive filler is formed by, for example, a metal material or a ceramic material. Heat transfer member 51 and heat transfer member 52 may be formed by, for example, a material having a thermal conductivity of greater than or equal to 1 W/m·K and less than or equal to several 10 W/m·K.

Substrate 60 has a first main surface 60a and a second main surface 60b. Second main surface 60b is a so-called mounting surface (C surface) of substrate 60. Second main surface 60b is a surface opposite to first main surface 60a. Second main surface 60b is in contact with second end 41b, fourth end 42b, and sixth end 43b. A base material of substrate 60 is, for example, a paper phenol substrate, a paper epoxy substrate, a glass composite substrate, a glass epoxy substrate, a polyimide substrate, a ceramic substrate such as an alumina substrate, or an aluminum core substrate. Substrate 60 may be a so-called flexible substrate. Between first main surface 60a and second main surface 60b, an insulating layer formed by an insulating material may be disposed. As the insulating material, a resin material having a thermal conductivity of 1 W/m·K to several 10 W/m·K, such as urethane resin, silicone resin, or epoxy resin, can be used. The insulating layer may be disposed between conductor layers of substrate 60.

On first main surface 60a, a circuit pattern 60c is formed. A thickness of circuit pattern 60c is, for example, greater than or equal to 1 μm and less than or equal to 200 μm. Circuit pattern 60c is formed by a conductive material. The conductive material is copper, nickel, aluminum, silver, tin, or an alloy of these. Note that circuit pattern 60c may also be formed inside second main surface 60b and substrate 60.

In substrate 60, a through hole 60d penetrating substrate 60 along a thickness direction is formed. Through hole 60d has, for example, a circular shape in plan view. An inner diameter of through hole 60d is, for example, greater than or equal to 0.6 mm and less than or equal to 1.5 mm. On an inner wall surface of through hole 60d, a conductor film 60e (not illustrated) is formed. Conductor film 60e has a thickness of greater than or equal to 0.01 mm and less than or equal to 0.1 mm, for example. Conductor film 60e is electrically connected to circuit pattern 60c.

Capacitor 10a is connected to substrate 60. More specifically, in a state where lead wire 10ab is inserted into through hole 60d, lead wire 10ab is connected to conductor film 60e and to circuit pattern 60c around through hole 60d, by a connection member 60f. Connection member 60f is formed by, for example, a solder alloy.

### (Assembly Method of Circuit Device 100)

Hereinafter, an assembly method for circuit device 100 will be described.

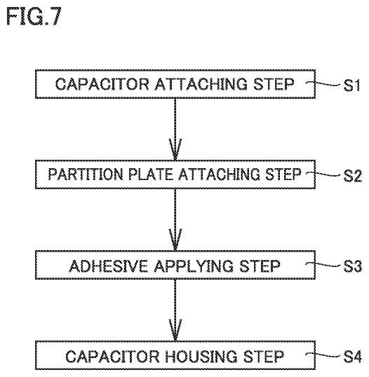

FIG. 7 is a process flowchart illustrating an assembly method for circuit device 100. As illustrated in FIG. 7, the assembly method for circuit device 100 has a capacitor attaching step S1, a partition plate attaching step S2, an adhesive applying step S3, and a capacitor housing step S4.

In capacitor attaching step S1, capacitor 10a is attached to substrate 60. More specifically, in a state where lead wire 10ab is inserted into through hole 60d, lead wire 10ab is soldered to conductor film 60e and to circuit pattern 60c around through hole 60d. This soldering is performed, for example, by flow soldering.

In partition plate attaching step S2, first partition plate 41 (third partition plate 43) and second partition plate 42 are attached to heat sink 30. First partition plate 41 (third partition plate 43) and second partition plate 42 are attached to heat sink 30 by, for example, an adhesive applied to upper surface 30a.

However, an attaching method for first partition plate 41 (third partition plate 43) and second partition plate 42 to heat sink 30 is not limited thereto. First partition plate 41 (third partition plate 43) and second partition plate 42 may be attached to heat sink 30 by swaging first partition plate 41 (third partition plate 43) and second partition plate 42 in a swaging groove formed in upper surface 30a. Further, first partition plate 41 (third partition plate 43) and second partition plate 42 may be attached to upper surface 30a (heat sink 30) by brazing while being inserted into a groove formed in upper surface 30a.

In adhesive applying step S3, adhesive 50 is applied onto upper surface 30a. Further, at this time, heat transfer member 51 and heat transfer member 52 may be applied to lead wire 10ab (side surface of capacitor 10a). In capacitor housing step S4, capacitor 10a is housed in a space surrounded by two adjacent first partition plates 41 (first partition plate 41 and third partition plate 43 adjacent to each other or two adjacent third partition plates 43), two adjacent second partition plates 42, and upper surface 30a. As a result, a top surface of capacitor 10a comes into contact with upper surface 30a with adhesive 50 interposed therebetween, and a side surface of capacitor 10a comes into contact with first partition plate 41 (third partition plate 43) with heat transfer member 51 (heat transfer member 52) interposed therebetween.

### (Effects of Circuit Device 100)

Hereinafter, an effect of circuit device 100 will be described.

In circuit device 100, heat generated in capacitor 10a (capacitor element body 10aa) is dissipated from heat sink 30 through a top surface of capacitor 10a and adhesive 50 (hereinafter referred to as “first heat dissipation path”). Therefore, according to circuit device 100, it is possible to suppress a temperature rise of capacitor 10a accompanying an operation of circuit device 100.

The first heat dissipation path similarly functions for both capacitor 10a (capacitor 10a at an end) between first partition plate 41 and third partition plate 43 and capacitor 10a (capacitor 10a at a center) between two adjacent third partition plates 43. Therefore, according to circuit device 100, a temperature gradient between capacitor 10a at the end and capacitor 10a at the center can be reduced.

Further, in circuit device 100, heat generated in capacitor 10a is dissipated from the heat sink through a side surface (lead wire 10ab) of capacitor 10a, heat transfer member 51 (heat transfer member 52), and first partition plate 41 (third partition plate 43) (hereinafter referred to as “second heat dissipation path”). Therefore, according to circuit device 100, heat can be dissipated by the second heat dissipation path in addition to the first heat dissipation path, and a temperature rise of capacitor 10a accompanying an operation of circuit device 100 can be further suppressed.

In circuit device 100, a contact area between third partition plate 43 and upper surface 30a is larger than a contact area between first partition plate 41 and upper surface 30a. Therefore, a contact thermal resistance value between third partition plate 43 and upper surface 30a is smaller than a contact thermal resistance value between first partition plate 41 and upper surface 30a.

Capacitors 10a are disposed on both sides of third partition plate 43. On the other hand, capacitor 10a is disposed only on one side of first partition plate 41. Therefore, third partition plate 43 receives a larger amount of heat from capacitor 10a than first partition plate 41. A temperature rise value of a partition plate is expressed by Δt=Q×(Rₐ+R_{b}) (hereinafter, referred to as “Equation 1”). Here, Δt is a temperature rise value of the partition plate, Q is an amount of heat from capacitor 10a, Rₐ is a thermal resistance value of the partition plate, and R_{b} is a contact thermal resistance value of the partition plate.

Third partition plate 43 has a larger thickness and a larger contact area between with upper surface 30a than those of first partition plate 41. From another point of view of this fact, Rₐ and R_{b} of third partition plate 43 are smaller than Rₐ and R_{b} of first partition plate 41. Therefore, according to circuit device 100, an increase in Δt can be suppressed even when a value of Q is large in third partition plate 43, and a temperature gradient between capacitor 10a between first partition plate 41 and third partition plate 43 adjacent to each other and capacitor 10a between two adjacent third partition plates 43 can be further reduced.

In circuit device 100, substrate 60 is used to connect capacitors 10a. As a result, since an insulative base material of substrate 60 is between lead wire 10ab on a positive electrode side and lead wire 10ab on a negative electrode side, lead wire 10ab on the positive electrode side and lead wire 10ab on the negative electrode side are prevented from coming into contact with each other even if substrate 60 is deformed due to external impact/vibration. As described above, according to circuit device 100, vibration resistance and impact resistance can be improved. In addition, in circuit device 100, since complicated and high-density wiring can be performed by substrate 60, capacitor 10a can be mounted at high density.

In circuit device 100, thermal diffusion (thermal radiation) between two adjacent capacitors 10a can be suppressed by first partition plate 41 (second partition plate 42, third partition plate 43), so that capacitor 10a can be electrically optimally disposed without being thermally restricted. In circuit device 100, first partition plate 41, second partition plate 42, and third partition plate 43 function as electromagnetic shields. For example, in a case where circuit component 10 is inductor 10b, a leakage magnetic flux from inductor 10b is shielded by first partition plate 41, second partition plate 42, and third partition plate 43, so that magnetic interference with other inductors 10b is suppressed.

In circuit device 100, first partition plate 41, second partition plate 42, and third partition plate 43 function as fire walls. For example, when a spark of discharge is generated from capacitor 10a due to a failure of capacitor 10a, the spark is blocked by first partition plate 41, second partition plate 42, and third partition plate 43, and an impact on other capacitors 10a is prevented.

In circuit device 100, by increasing or decreasing the number of first partition plates 41, second partition plates 42, and third partition plates 43, the number and size a space surrounded by two adjacent first partition plates 41 (first partition plate 41 and third partition plate 43 adjacent to each other or two adjacent third partition plates 43), two adjacent second partition plates 42, and upper surface 30a can be changed in accordance with the number and size of capacitors 10a.

In circuit device 100, thicknesses, types, plate thicknesses, and the like of first partition plate 41, second partition plate 42, and third partition plate 43 can be freely selected. As described above, according to circuit device 100, it is possible to realize various uses flexibly and at low cost.

A thermal conductivity of lead wire 10ab is higher than a thermal conductivity of capacitor element body 10aa, and heat generated in capacitor element body 10aa is easily thermally conducted to lead wire 10ab. Therefore, in a case where heat transfer member 51 (heat transfer member 52) is disposed between first partition plate 41 (third partition plate 43) and lead wire 10ab, it is possible to suppress a usage amount of heat transfer member 51 (heat transfer member 52) while maintaining heat dissipation from the second heat dissipation path. That is, in this case, a weight of circuit device 100 can be reduced.

In a case where heat transfer member 51 (heat transfer member 52) is disposed between first partition plate 41 (third partition plate 43) and a surface of capacitor element body 10aa to which lead wire 10ab is attached, insulation between lead wire 10ab and first partition plate 41 (third partition plate 43) can be secured, so that a thickness of heat transfer member 51 (heat transfer member 52) can be reduced. As a result, heat dissipation from the second heat dissipation path can be improved on the basis of Equation 2 described later. Furthermore, in this case, since insulation between lead wire 10ab and first partition plate 41 (third partition plate 43) can be secured, heat transfer member 51 (heat transfer member 52) having conductivity can be used. Heat transfer member 51 (heat transfer member 52) having conductivity has a higher thermal conductivity than insulative heat transfer member 51 (heat transfer member 52). Therefore, in this case, a property of heat dissipation from the second heat dissipation path can be further enhanced.

Further, in a case where heat transfer member 51 (heat transfer member 52) is disposed between first partition plate 41 (third partition plate 43) and lead wire 10ab, and heat transfer member 51 (heat transfer member 52) is also disposed between first partition plate 41 (third partition plate 43) and a surface of capacitor element body 10aa to which lead wire 10ab is attached, an area of heat transfer member 51 (heat transfer member 52) is increased, so that heat dissipation from the second heat dissipation path is improved on the basis of Equation 2 to be described later. As a contact area between heat transfer member 51 (heat transfer member 52) and first partition plate 41 (third partition plate 43) is larger, heat transfer member 51 (heat transfer member 52) is less likely to peel off.

In a case where heat transfer member 51 (heat transfer member 52) is disposed between first partition plate 41 (third partition plate 43) and lead wire 10ab, it is necessary to apply heat transfer member 51 (heat transfer member 52) so as not to adhere to a portion other than lead wire 10ab. On the other hand, in a case where heat transfer member 51 (heat transfer member 52) is disposed between first partition plate 41 (third partition plate 43) and a surface of capacitor element body 10aa to which lead wire 10ab is attached, it is necessary to apply heat transfer member 51 (heat transfer member 52) so as not to adhere to lead wire 10ab. As a result, in these cases, it is necessary to carefully apply heat transfer member 51 (heat transfer member 52), and it takes time for application work of heat transfer member 51 (heat transfer member 52).

In a case where heat transfer member 51 (heat transfer member 52) is disposed between first partition plate 41 (third partition plate 43) and lead wire 10ab, and heat transfer member 51 (heat transfer member 52) is also disposed between first partition plate 41 (third partition plate 43) and a surface of capacitor element body 10aa to which lead wire 10ab is attached, the attention as described above is unnecessary, the application work of heat transfer member 51 (heat transfer member 52) can be simplified.

### Modification 1

Circuit device 100 (hereinafter referred to as “circuit device 100A”) according to Modification 1 will be described.

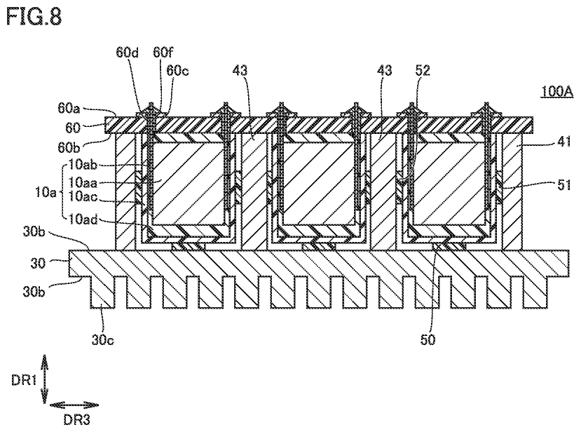

FIG. 8 is a cross-sectional view of circuit device 100A. FIG. 8 illustrates a cross section of circuit device 100A at a position corresponding to VI-VI in FIG. 2. As illustrated in FIG. 8, in circuit device 100A, capacitor 10a further has an exterior case 10ac and a sealing resin 10ad. In circuit device 100A, capacitor element body 10aa and lead wire 10ab are disposed in exterior case 10ac. Sealing resin 10ad resin-seals capacitor element body 10aa and lead wire 10ab by filling exterior case 10ac.

In circuit device 100, it is necessary to increase a thickness of heat transfer member 51 (heat transfer member 52) in order to secure an insulation distance between lead wire 10ab and first partition plate 41 (third partition plate 43). On the other hand, in circuit device 100A, since insulation between lead wire 10ab and first partition plate 41 (third partition plate 43) can be secured by exterior case 10ac, a thickness of heat transfer member 51 (heat transfer member 52) can be reduced.

Thermal resistance of heat transfer member 51 (heat transfer member 52) is expressed by R=L/(A_{c}×λ) (hereinafter, referred to as “Equation 2”). Here, R is thermal resistance of heat transfer member 51 (heat transfer member 52), L is a thickness of heat transfer member 51 (heat transfer member 52), λ is a thermal conductivity of heat transfer member 51 (heat transfer member 52), and A_{c} is a cross-sectional area of heat transfer member 51 (heat transfer member 52). As described above, in circuit device 100A, since the value of L can be reduced, heat dissipation from the second heat dissipation path can be improved.

### Modification 2

Circuit device 100 (hereinafter referred to as “circuit device 100B”) according to Modification 2 will be described.

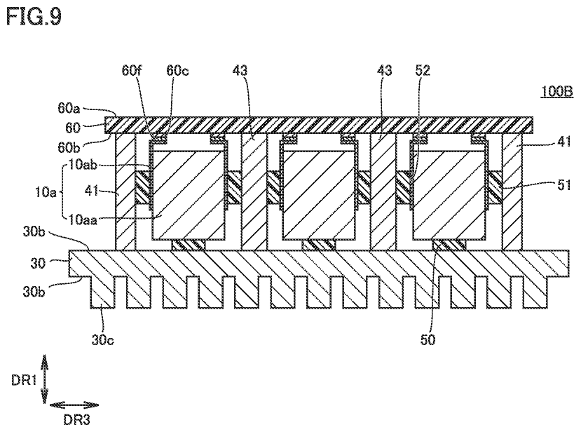

FIG. 9 is a cross-sectional view of circuit device 100B. FIG. 9 illustrates a cross-sectional view of circuit device 100B at a position corresponding to VI-VI in FIG. 2. As illustrated in FIG. 9, in circuit device 100B, through hole 60d is not formed in substrate 60. In circuit device 100B, circuit pattern 60c connected to lead wire 10ab is disposed on second main surface 60b.

An assembly method for circuit device 100B is different from the assembly method for circuit device 100 in capacitor attaching step S1. In capacitor attaching step S1 in the assembly method for circuit device 100B, first, connection member 60f is applied onto circuit pattern 60c on second main surface 60b by using, for example, a printing machine. Secondly, capacitor 10a is disposed such that lead wire 10ab is located on connection member 60f. Thirdly, reflow-type soldering is performed by heating connection member 60f to a temperature greater than or equal to a melting point, and lead wire 10ab and circuit pattern 60c are joined by connection member 60f.

### Modification 3

Circuit device 100 (hereinafter referred to as “circuit device 100C”) according to Modification 3 will be described.

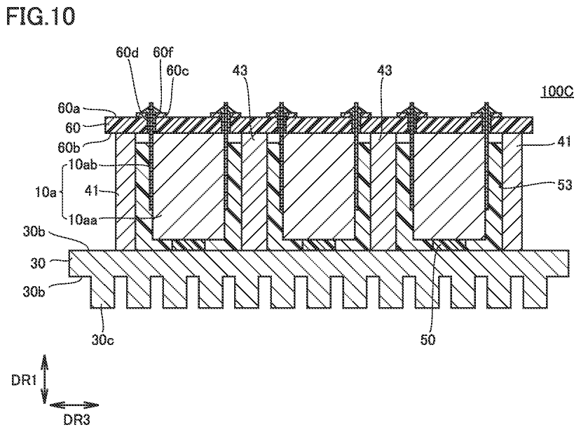

FIG. 10 is a cross-sectional view of circuit device 100C. FIG. 10 illustrates a cross section of circuit device 100C at a position corresponding to VI-VI in FIG. 2. As illustrated in FIG. 10, in circuit device 100C, a sealing member 53 is used as heat transfer member 51 and heat transfer member 52. Sealing member 53 is made to fill a space surrounded by two adjacent first partition plates 41 (first partition plate 41 and third partition plate 43 adjacent to each other or two adjacent third partition plates 43), two adjacent second partition plates 42, and upper surface 30a

As a result, capacitor 10a is sealed by sealing member 53, in a space surrounded by two adjacent first partition plates 41 (first partition plate 41 and third partition plate 43 adjacent to each other or two adjacent third partition plates 43), two adjacent second partition plates 42, third partition plate 43, and upper surface 30a.

Sealing member 53 is formed by an electrically insulative material. A thermal conductivity of a material contained in sealing member 53 is preferably greater than or equal to 0.1 W/m·K. A thermal conductivity of a material contained in sealing member 53 is more preferably greater than or equal to 1.0 W/m·K. A Young's modulus of the material contained in sealing member 53 is preferably greater than or equal to 1 MPa. Sealing member 53 is formed by, for example, a resin material such as polyphenylene sulfide (PPS) or polyetheretherketone (PEEK), containing a thermally conductive filler. Sealing member 53 may be formed by a rubber material such as epoxy, silicone, and urethane.

In circuit device 100B, heat from capacitor 10a is dissipated from heat sink 30 via a side surface of capacitor 10a, sealing member 53, and first partition plate 41 (third partition plate 43) (hereinafter referred to as “third heat dissipation path”), in addition to the first heat dissipation path. As described above, according to circuit device 100B, since heat can be dissipated by the first heat dissipation path and the third heat dissipation path, it is possible to suppress a temperature rise of capacitor 10a accompanying an operation of circuit device 100B.

### Modification 4

Circuit device 100 (hereinafter referred to as “circuit device 100D”) according to Modification 4 will be described.

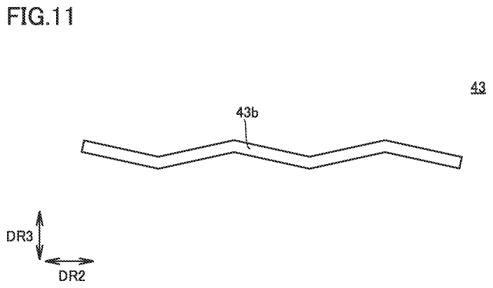

FIG. 11 is a top view of third partition plate 43 included in circuit device 100D. As illustrated in FIG. 11, third partition plate 43 extends in second direction DR2 in a zigzag shape in second direction DR2, when viewed from first direction DR1. In circuit device 100D, a thickness of third partition plate 43 in third direction DR3 may be larger than a thickness of first partition plate 41 in third direction DR3, or may be equal to the thickness of first partition plate 41 in third direction DR3.

In circuit device 100D, since third partition plate 43 extends in a zigzag shape when viewed from first direction DR1, a contact area between third partition plate 43 and upper surface 30a increases, and a contact thermal resistance value between third partition plate 43 and upper surface 30a decreases. Therefore, according to circuit device 100D, a temperature gradient between capacitor 10a between first partition plate 41 and third partition plate 43 adjacent to each other and capacitor 10a between two adjacent third partition plates 43 can be further reduced.

### Other Modifications

As circuit component 10 used in circuit devices 100 to 100D, any of capacitor 10a, inductor 10b, contactor 10c, discharge resistor 10d, and charge resistor 10e may be disposed. In addition, without limiting to this, any component that generates heat can be used as circuit component 10 in circuit devices 100 to 100D.

Further, in circuit devices 100 to 100D, only one circuit component 10 may be disposed in one section, or a plurality of circuit components 10 may be disposed in one section. In a case where one circuit component 10 is disposed in one section, all the cooling capabilities of the one section can be used for the one circuit component 10. In a case where a plurality of circuit components 10 are disposed in one section, the cooling capacity is divided, but circuit component 10 can be more efficiently disposed if circuit component 10 is small and the section is large.

Furthermore, in circuit devices 100 to 100D, there may be a section (disposition section) in which circuit component 10 is disposed and a section (non-disposition section) in which circuit component 10 is not disposed. In this case, the cooling effect of circuit component 10 disposed in the disposition section adjacent to the non-disposition section can be further enhanced, and circuit component 10 can be cooled more effectively.

### Second Embodiment

A circuit device (hereinafter referred to as “circuit device 200”) according to a second embodiment will be described. Hereinafter, differences from circuit device 100 will be mainly described, and redundant descriptions will not be repeated.

### (Configuration of Circuit Device 200)

Hereinafter, a configuration of circuit device 200 will be described.

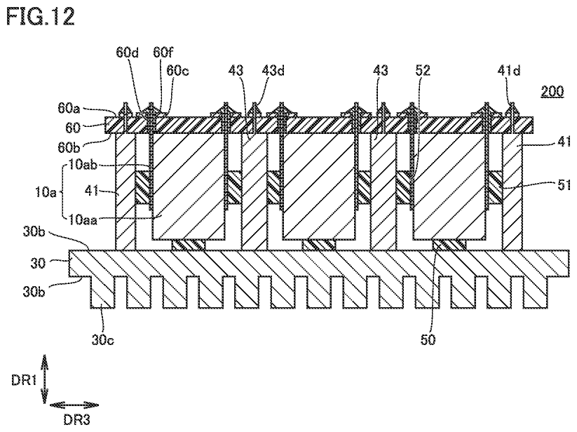

FIG. 12 is a cross-sectional view of circuit device 200. FIG. 12 illustrates a cross section of circuit device 200 at a position corresponding to VI-VI in FIG. 2.

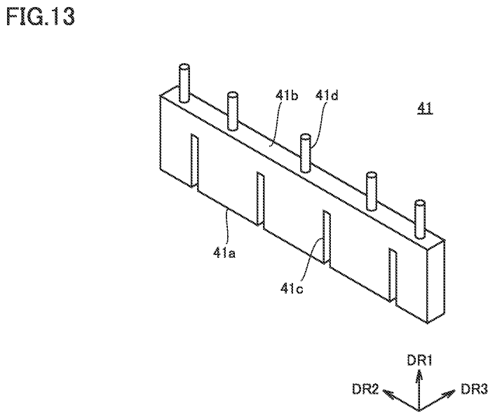

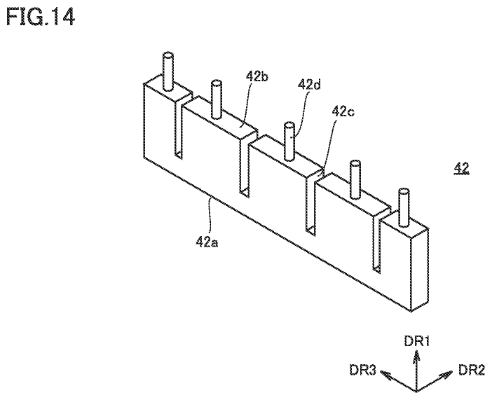

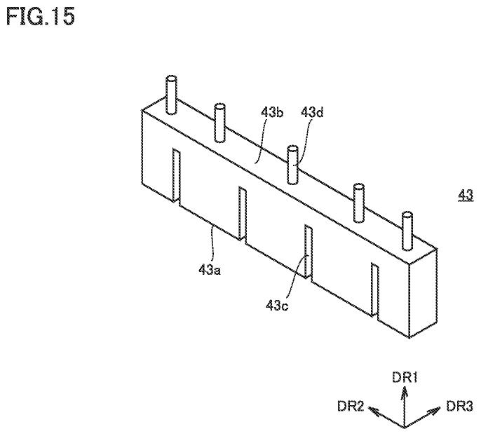

FIG. 13 is a perspective view of a first partition plate 41 included in circuit device 200. FIG. 14 is a perspective view of a second partition plate 42 included in circuit device 200. FIG. 15 is a perspective view of a third partition plate 43 included in circuit device 200. As illustrated in FIGS. 12 to 15, circuit device 200 has a circuit component 10 (capacitor 10a), a heat sink 30, a plurality of first partition plates 41, a plurality of second partition plates 42, an adhesive 50, a heat transfer member 51, a heat transfer member 52, and a substrate 60. First partition plate 41 at a position other than both ends in a third direction DR3 is third partition plate 43. In this regard, the configuration of circuit device 200 is in common with the configuration of circuit device 100.

In circuit device 200, first partition plate 41, second partition plate 42, and third partition plate 43 respectively have a terminal 41d, a terminal 42d, and a terminal 43d. In this regard, the configuration of circuit device 200 is different from the configuration of circuit device 100.

Terminal 41d protrudes from a second end 41b along a first direction DR1. Terminal 41d is integrally formed by, for example, the same material as first partition plate 41. Terminal 42d protrudes from a fourth end 42b along first direction DR1. Terminal 42d is integrally formed by, for example, the same material as second partition plate 42. Terminal 43d protrudes from sixth end 43b along first direction DR1. Terminal 43d is integrally formed by, for example, the same material as third partition plate 43. Terminal 41d, terminal 42d, and terminal 43d are formed by performing cutting processing, for example, on first partition plate 41, second partition plate 42, and third partition plate 43, respectively.

Terminal 41d, terminal 42d, and terminal 43d are inserted into through holes 60d. As a result, fixing of substrate 60 is performed. Note that through holes 60d into which terminal 41d, terminal 42d, and terminal 43d are inserted are different from through hole 60d into which a lead wire 10ab is inserted. Plating is preferably formed on surfaces of terminal 41d, terminal 42d, and terminal 43d. This plating is formed by, for example, a metal material that is easily soldered. This plating is formed by, for example, copper, tin, nickel, or brass. Terminal 41d, terminal 42d, and terminal 43d are preferably soldered to a circuit pattern 60c around through hole 60d.

### (Assembly Method of Circuit Device 200)

Hereinafter, an assembly method for circuit device 200 will be described.

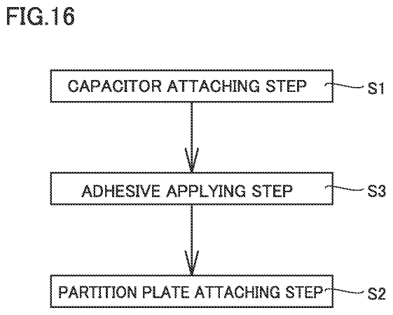

FIG. 16 is a process flowchart illustrating an assembly method for circuit device 200. As illustrated in FIG. 16, the assembly method for circuit device 200 has a capacitor attaching step S1, a partition plate attaching step S2, and an adhesive applying step S3. In this regard, the assembly method for circuit device 200 is in common with the assembly method for circuit device 100.

The assembly method for circuit device 200 does not have a capacitor housing step S4. Further, in capacitor attaching step S1 in the assembly method for circuit device 200, in addition to flow soldering of lead wire 10ab, flow soldering of terminal 41d, terminal 42d, and terminal 43d is performed. Furthermore, in the assembly method for circuit device 200, partition plate attaching step S2 is performed after adhesive applying step S3. In this regard, the assembly method for circuit device 200 is different from the assembly method for circuit device 100.

### (Effects of Circuit Device 200)

Hereinafter, an effect of circuit device 200 will be described.

In circuit device 100 and circuit device 200, substrate 60 has a high temperature due to heat from capacitor 10a. In circuit device 100, heat of substrate 60 is sequentially transferred to capacitor 10a, heat transfer member 51 (heat transfer member 52), first partition plate 41 (third partition plate 43), and heat sink 30, and is dissipated from heat sink 30.

On the other hand, in circuit device 200, heat of substrate 60 is sequentially transferred to terminal 41d (terminal 43d), first partition plate 41 (third partition plate 43), and the heat sink, and is dissipated from heat sink 30 (hereinafter referred to as “fourth heat dissipation path”). That is, in circuit device 200, the heat dissipation path of heat from substrate 60 is shortened as compared with circuit device 100. As described above, since circuit device 200 has the fourth heat dissipation path, it is possible to suppress a temperature rise of substrate 60, and thus, it is possible to further suppress a temperature rise of capacitor 10a connected to substrate 60.

### Modification 1

Circuit device 200 (hereinafter referred to as “circuit device 200A”) according to Modification 1 will be described.

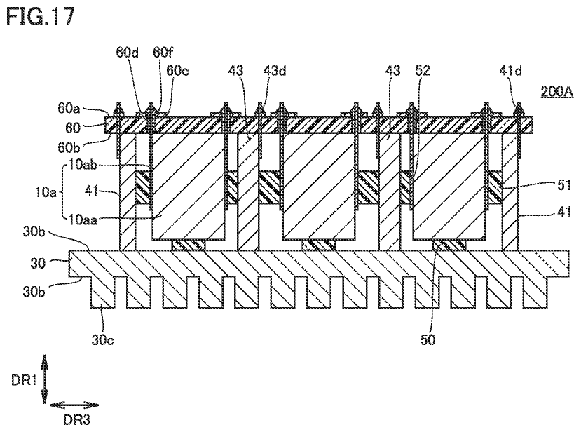

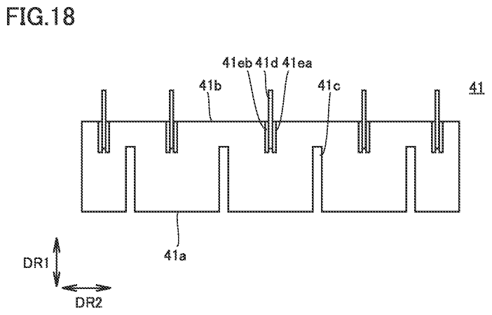

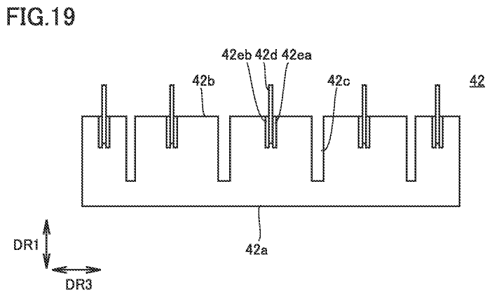

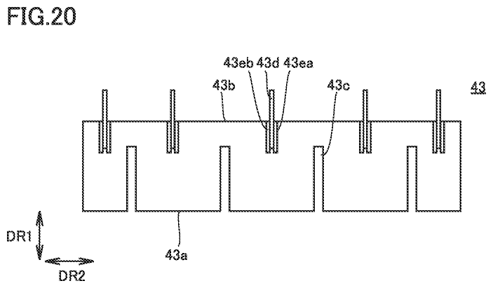

FIG. 17 is a cross-sectional view of circuit device 200A. FIG. 17 illustrates a cross section of circuit device 200A at a position corresponding to VI-VI in FIG. 2. FIG. 18 is a plan view of first partition plate 41 included in circuit device 200A. FIG. 19 is a plan view of second partition plate 42 included in circuit device 200A. FIG. 20 is a plan view of third partition plate 43 included in circuit device 200A.

As illustrated in FIGS. 17 and 18, a vertical wall portion 41ea and a vertical wall portion 41eb are formed on side surfaces of first partition plate 41. Vertical wall portions 41ea and 41eb face each other with an interval therebetween in a second direction DR2. Terminal 41d is disposed between vertical wall portions 41ea and 41eb. Terminal 41d is attached to first partition plate 41 by being swaged to vertical wall portions 41ea and 41eb.

As illustrated in FIGS. 17 and 19, a vertical wall portion 42ea and a vertical wall portion 42eb are formed on side surfaces of second partition plate 42. Vertical wall portions 42ea and 42eb face each other with an interval therebetween in third direction DR3. Terminal 42d is disposed between vertical wall portions 42ea and 42eb. Terminal 42d is attached to second partition plate 42 by being swaged to vertical wall portions 42ea and 42eb.

As illustrated in FIGS. 17 and 20, a vertical wall portion 43ea and a vertical wall portion 43eb are formed on side surfaces of third partition plate 43. Vertical wall portions 43ea and 43eb face each other with an interval therebetween in second direction DR2. Terminal 43d is disposed between vertical wall portions 43ea and 43eb. Terminal 43d is attached to third partition plate 43 by being swaged to vertical wall portions 43ea and 43eb.

Terminal 41d, terminal 42d, and terminal 43d are preferably formed by a metal material that is easily soldered, such as copper, tin, nickel, or brass. Note that plating may not be formed on surfaces of terminal 41d, terminal 42d, and terminal 43d.

First partition plate 41 having vertical wall portions 41ea and 41eb, second partition plate 42 having vertical wall portions 42ea and 42eb, and third partition plate 43 having vertical wall portions 43ea and 43eb may be formed by milling processing or extrusion molding. However, a processing method for first partition plate 41, second partition plate 42, and third partition plate 43 is not limited to those described above.

In circuit device 200, in a case where first partition plate 41, second partition plate 42, and third partition plate 43 are formed by a material that is not easily soldered, such as aluminum, surfaces of terminal 41d, terminal 42d, and terminal 43d need to be plated with a material that is easily soldered.

In circuit device 200A, terminal 41d, terminal 42d, and terminal 43d can be formed by a material different from those of first partition plate 41, second partition plate 42, and third partition plate 43. Therefore, according to circuit device 200A, even in a case where first partition plate 41, second partition plate 42, and third partition plate 43 are formed by a material that is not easily soldered, the plating step for the surfaces of terminal 41d, terminal 42d, and terminal 43d can be omitted by forming terminal 41d, terminal 42d, and terminal 43d with a material that is easily soldered.

### Modification 2

Circuit device 200 (hereinafter referred to as “circuit device 200B”) according to Modification 2 will be described.

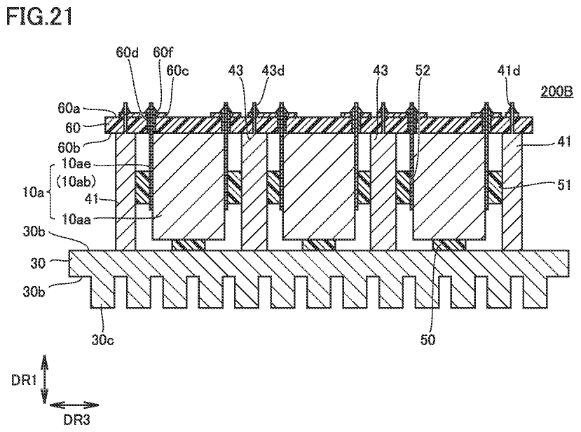

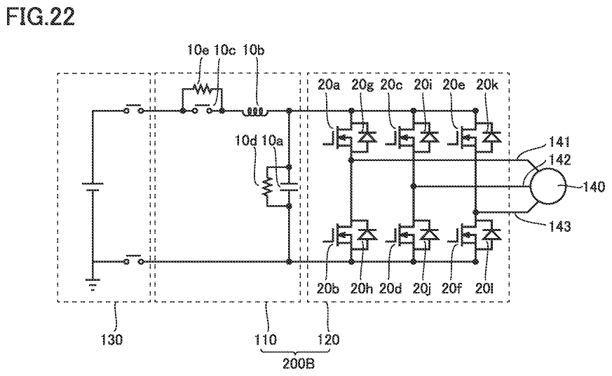

FIG. 21 is a cross-sectional view of circuit device 200B. FIG. 21 illustrates a cross section of circuit device 200B at a position corresponding to VI-VI in FIG. 2. FIG. 22 is a circuit diagram of circuit device 200B. Lead wire 10ab forming a negative electrode of capacitor 10a is referred to as a lead wire 10ae. As illustrated in FIG. 22, terminal 41d, terminal 42d, and terminal 43d are connected to circuit pattern 60c that is connected to lead wire 10ae. As illustrated in FIG. 22, in circuit device 200B, a negative electrode of a DC supply circuit 130 is connected to a ground terminal.

Substrate 60 has a high temperature at a connection portion between with lead wire 10ae. In circuit device 200B, the connection portion of lead wire 10ae is connected to terminal 41d, terminal 42d, and terminal 43d by circuit pattern 60c. A thermal conductivity of circuit pattern 60c is higher than a thermal conductivity of a base material of substrate 60. Therefore, in circuit device 200B, thermal resistance of substrate 60 in the fourth heat dissipation path is reduced, and heat dissipation from the fourth heat dissipation path is further enhanced.

In a case where heat sink 30 (including first partition plate 41, second partition plate 42, and third partition plate 43) is grounded, heat sink 30 can be made function as negative electrode wiring of DC supply circuit 130. Therefore, in this case, electric wires required for DC supply circuit 130 and circuit pattern 60c formed on substrate 60 can be reduced.

### Third Embodiment

A circuit device (hereinafter referred to as “circuit device 300”) according to a third embodiment will be described. Hereinafter, differences from circuit device 100 will be mainly described, and redundant descriptions will not be repeated.

### (Configuration of Circuit Device 300)

Hereinafter, a configuration of circuit device 300 will be described.

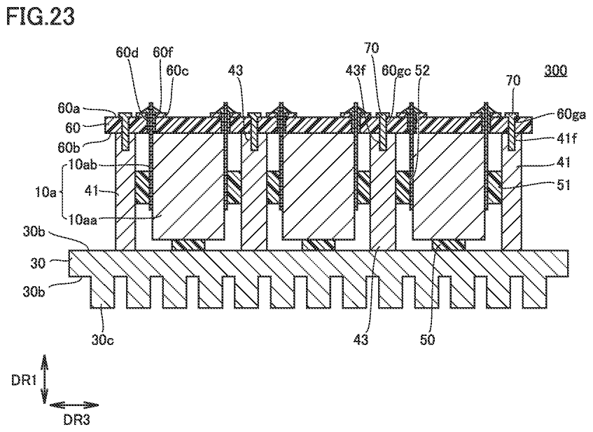

FIG. 23 is a cross-sectional view of circuit device 300. FIG. 23 illustrates a cross section of circuit device 300 at a position corresponding to VI-VI in FIG. 2.

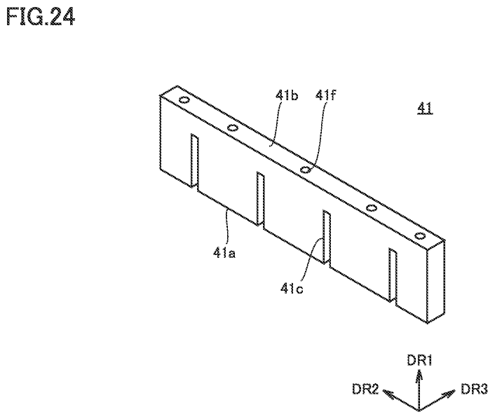

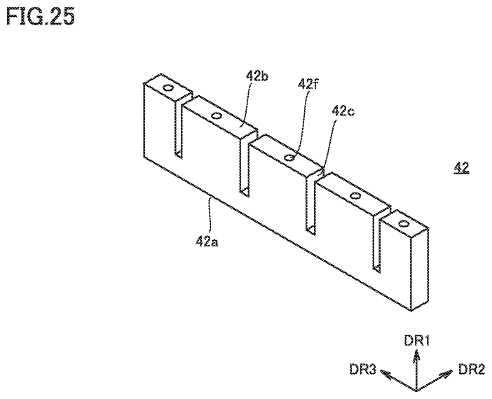

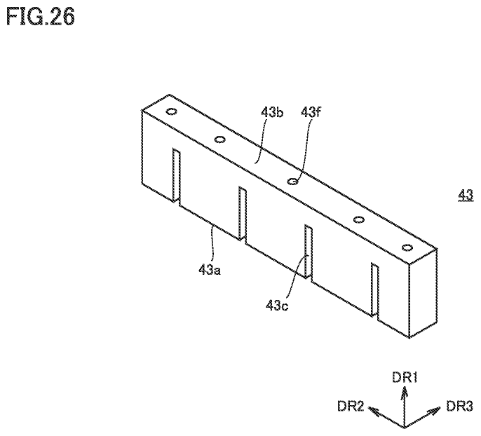

FIG. 24 is a perspective view of a first partition plate 41 included in circuit device 300. FIG. 25 is a perspective view of a second partition plate 42 included in circuit device 300. FIG. 26 is a perspective view of a third partition plate 43 included in circuit device 300. As illustrated in FIGS. 23 to 26, circuit device 300 has a circuit component 10 (capacitor 10a), a heat sink 30, a plurality of first partition plates 41, a plurality of second partition plates 42, an adhesive 50, a heat transfer member 51, a heat transfer member 52, and a substrate 60. First partition plate 41 at a position other than both ends in a third direction DR3 is third partition plate 43. In this regard, the configuration of circuit device 300 is in common with the configuration of circuit device 100.

In circuit device 300, a screw hole 41f, a screw hole 42f, and a screw hole 43f are formed in first partition plate 41, second partition plate 42, and third partition plate 43, respectively. Screw hole 41f, screw hole 42f, and screw hole 43f are formed at a second end 41b, a fourth end 42b, and a sixth end 43b, respectively. In circuit device 300, a penetration hole 60ga, a penetration hole 60gb (not illustrated), and a penetration hole 60gc are formed in substrate 60. Circuit device 300 further has a screw 70.

Screw 70 is passed through penetration hole 60ga and then screwed into screw hole 41f. Screw 70 is passed through penetration hole 60gb and then screwed into screw hole 42f Screw 70 is passed through penetration hole 60gc and then screwed into screw hole 43f As a result, substrate 60 is fixed. In this regard, the configuration of circuit device 300 is different from the configuration of circuit device 100.

### (Assembly Method of Circuit Device 300)

Hereinafter, an assembly method for circuit device 300 will be described.

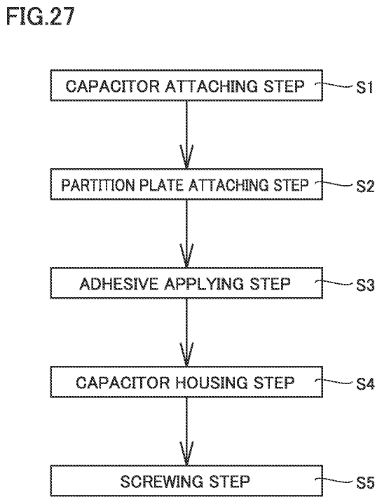

FIG. 27 is a process flowchart illustrating an assembly method for circuit device 300. As illustrated in FIG. 27, the assembly method for circuit device 300 has a capacitor attaching step S1, a partition plate attaching step S2, an adhesive applying step S3, and a capacitor housing step S4. In this regard, the assembly method for circuit device 300 is in common with the assembly method for circuit device 100.

The assembly method for circuit device 300 further has a screwing step S5. In screwing step S5, screw 70 is passed through penetration hole 60ga and then screwed into screw hole 41f, screw 70 is passed through penetration hole 60gb and then screwed into screw hole 42f, and screw 70 is passed through penetration hole 60gc and then screwed into screw hole 43f. In this regard, the assembly method for circuit device 300 is different from the assembly method for circuit device 100.

### (Effects of Circuit Device 300)

Hereinafter, an effect of circuit device 300 will be described.

In circuit device 100 and circuit device 300, substrate 60 has a high temperature due to heat from capacitor 10a. In circuit device 100, heat of substrate 60 is sequentially transferred to capacitor 10a, heat transfer member 51 (heat transfer member 52), first partition plate 41 (third partition plate 43), and heat sink 30, and is dissipated from heat sink 30.

On the other hand, in circuit device 300, heat of substrate 60 is sequentially transferred to screw 70, first partition plate 41 (third partition plate 43), and the heat sink, and is dissipated from heat sink 30 (hereinafter referred to as “fifth heat dissipation path”). That is, in circuit device 300, the heat dissipation path of heat from substrate 60 is shortened as compared with circuit device 100. As described above, since circuit device 300 has the fifth heat dissipation path, it is possible to suppress a temperature rise of substrate 60, and thus, it is possible to further suppress a temperature rise of capacitor 10a connected to substrate 60.

In circuit device 100, substrate 60 is attached to heat sink 30 only by adhesive 50. On the other hand, in circuit device 300, substrate 60 is fixed to first partition plate 41, second partition plate 42, and third partition plate 43 by screw 70. Therefore, in circuit device 300, an impact and vibration applied to substrate 60 are also distributed to screw 70, and peeling of adhesive 50 from an upper surface 30a and peeling of heat transfer member 51 (heat transfer member 52) from first partition plate 41 (third partition plate 43) are suppressed. As a result, according to circuit device 300, even if an impact and vibration are applied to substrate 60, the first heat dissipation path and the second heat dissipation path are easily maintained.

### Fourth Embodiment

A circuit device (hereinafter referred to as “circuit device 400”) according to a fourth embodiment will be described. Hereinafter, differences from circuit device 100 will be mainly described, and redundant descriptions will not be repeated.

### (Configuration of Circuit Device 400)

Hereinafter, a configuration of circuit device 400 will be described.

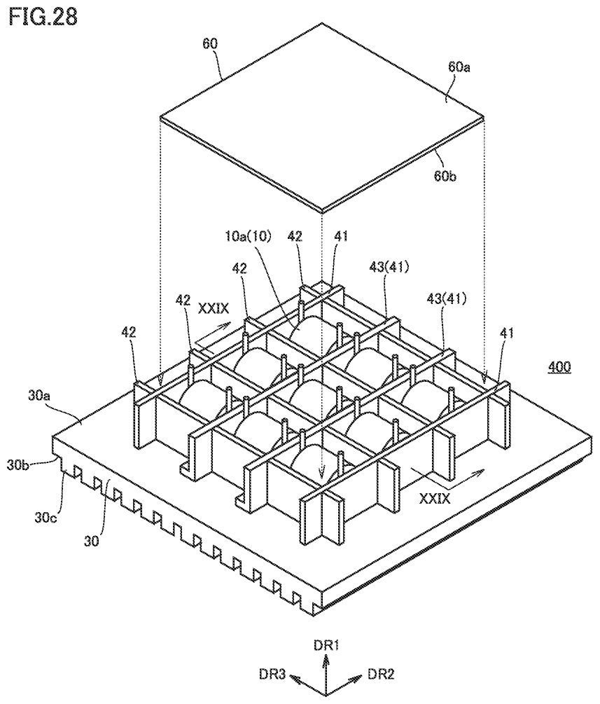

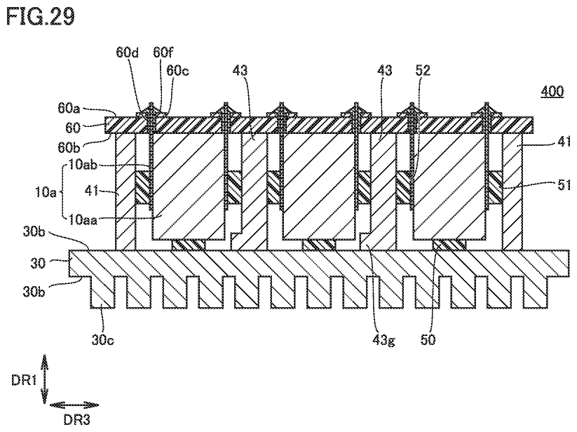

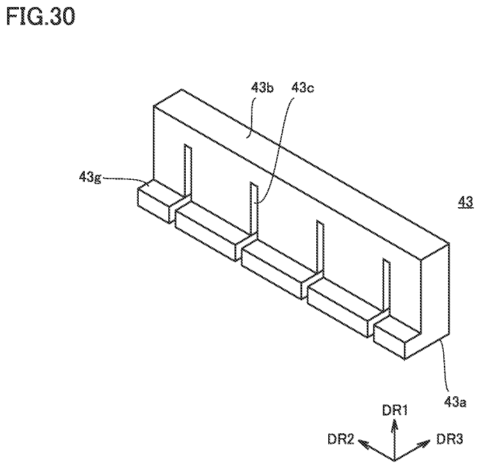

FIG. 28 is an exploded perspective view of circuit device 400. FIG. 29 is a cross-sectional view taken along line XXIX-XXIX in FIG. 28. FIG. 30 is a perspective view of a third partition plate 43 included in circuit device 400.

As illustrated in FIGS. 28 to 30, circuit device 400 has a circuit component 10 (capacitor 10a), a heat sink 30, a plurality of first partition plates 41, a plurality of second partition plates 42, an adhesive 50, a heat transfer member 51, a heat transfer member 52, and a substrate 60. First partition plate 41 at a position other than both ends in a third direction DR3 is third partition plate 43. In this regard, the configuration of circuit device 400 is in common with the configuration of circuit device 100.

In circuit device 400, third partition plate 43 has a support portion 43g. Support portion 43g is disposed at a fifth end 43a. In circuit device 400, third partition plate 43 is in contact with an upper surface 30a at support portion 43g. In this regard, the configuration of circuit device 400 is different from the configuration of circuit device 100.

Note that third partition plate 43 having support portion 43g is formed, for example, by forming a third insertion port 43c and then bending fifth end 43a side by press processing. A method of forming third partition plate 43 having support portion 43g is not limited thereto. Third partition plate 43 having support portion 43g may be formed by forming a sheet metal having support portion 43g by press processing or extrusion molding, and then forming third insertion port 43c by punching processing or cutting processing. Third partition plate 43 having support portion 43g may be formed by casting such as die casting. Third partition plate 43 having support portion 43g may be formed by joining a plurality of members by brazing, swaging, or the like, or bonding with an adhesive.

### (Effects of Circuit Device 400)

Hereinafter, an effect of circuit device 400 will be described.

In circuit device 400, since third partition plate 43 has support portion 43g, a contact area between third partition plate 43 and upper surface 30a is larger than that of circuit device 100. Therefore, in circuit device 400, a contact thermal resistance value between third partition plate 43 and upper surface 30a is smaller than that in circuit device 100.

As a result, according to circuit device 400, a temperature rise of third partition plate 43 having a large amount of heat received from capacitor 10a can be further suppressed, and a temperature rise of entire circuit device 400 can be suppressed.

Further, accordingly, as compared with circuit device 100, a temperature gradient between capacitor 10a between first partition plate 41 and third partition plate 43 adjacent to each other and capacitor 10a between two adjacent third partition plates 43 can be further reduced.

### Modification

Circuit device 400 (hereinafter referred to as “circuit device 400A”) according to a modification will be described.

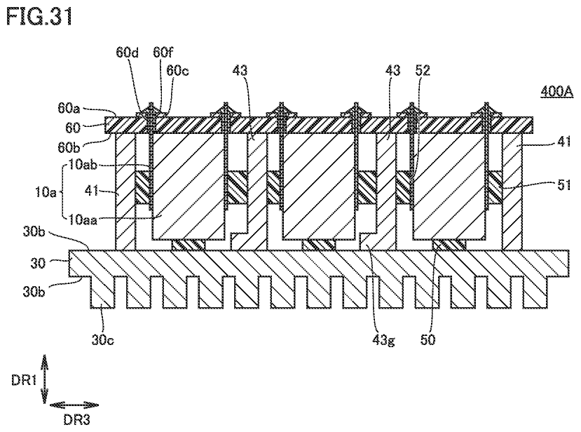

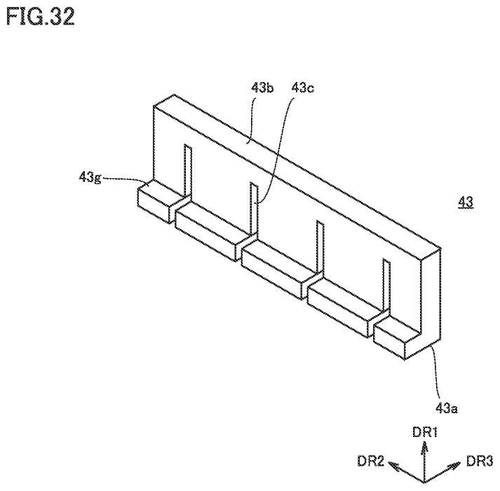

FIG. 31 is a cross-sectional view of circuit device 400A. FIG. 32 is a perspective view of third partition plate 43 included in circuit device 400A. FIG. 31 illustrates a cross section of circuit device 400A at a position corresponding to XXIX-XXIX in FIG. 28. As illustrated in FIGS. 31 and 32, in circuit device 400A, a thickness of third partition plate 43 in third direction DR3 is smaller than that of circuit device 400. For example, in circuit device 400A, the thickness of third partition plate 43 in third direction DR3 is equal to a thickness of first partition plate 41 in third direction DR3.

In circuit device 400A, since the thickness of third partition plate 43 is small, a weight of circuit device 400A can be reduced. Note that, in circuit device 400A, the thickness of third partition plate 43 is small, and thus a value of Rₐ in Equation 1 is large, but a value of R_{b} in Equation 1 is small because support portion 43g is included. Therefore, in circuit device 400A, a value of Δt in Equation 1, that is, a temperature rise of third partition plate 43 is suppressed.

Fifth embodiment.

A circuit device (hereinafter referred to as “circuit device 500”) according to a fifth embodiment will be described. Hereinafter, differences from circuit device 100 will be mainly described, and redundant descriptions will not be repeated.

### (Configuration of Circuit Device 500)

Hereinafter, a configuration of circuit device 500 will be described.

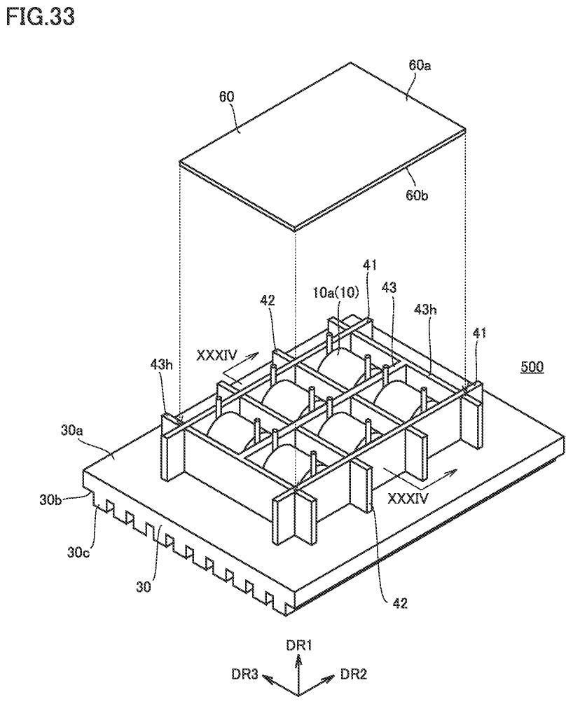

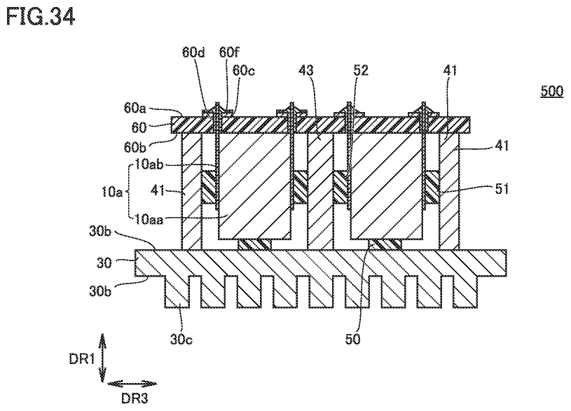

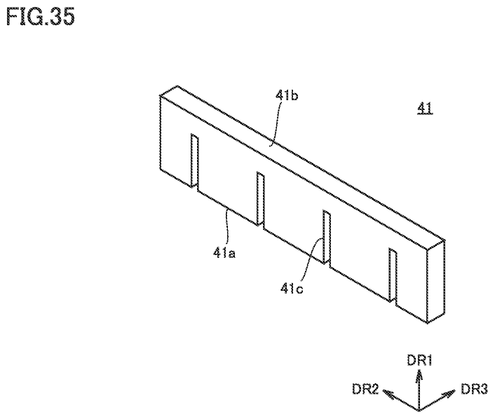

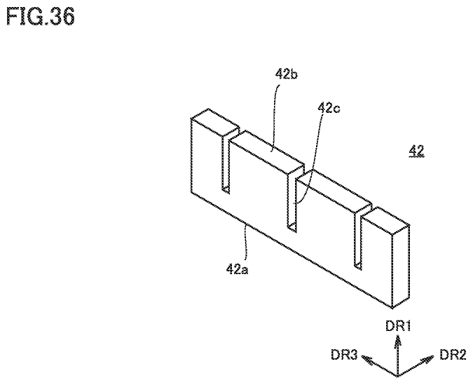

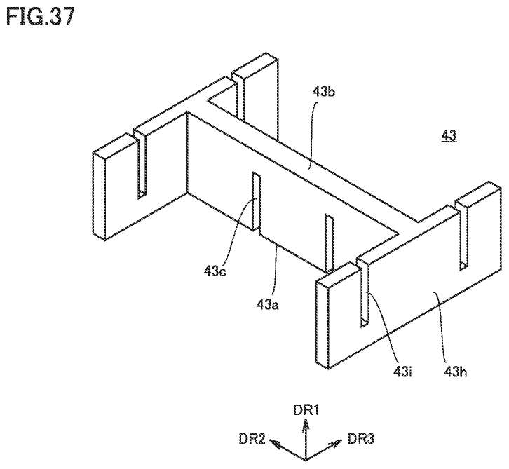

FIG. 33 is an exploded perspective view of circuit device 500. FIG. 34 is a cross-sectional view taken along line XXXIV-XXXIV in FIG. 33. Further, FIG. 35 is a perspective view of a first partition plate 41 included in circuit device 500. FIG. 36 is a perspective view of a second partition plate 42 included in circuit device 500. FIG. 37 is a perspective view of a third partition plate 43 included in circuit device 500. As illustrated in FIGS. 33 to 36, circuit device 500 has a circuit component 10 (capacitor 10a), a heat sink 30, a plurality of first partition plates 41, a plurality of second partition plates 42, an adhesive 50, a heat transfer member 51, a heat transfer member 52, and a substrate 60. First partition plate 41 at a position other than both ends in a third direction DR3 is third partition plate 43. In this regard, the configuration of circuit device 500 is in common with the configuration of circuit device 100.

In circuit device 500, third partition plate 43 has a heat dissipation plate 43h. Heat dissipation plate 43h extends in a third direction DR3. Heat dissipation plate 43h is at both ends of third partition plate 43 in a second direction DR2. A plurality of fourth insertion ports 43i are formed at a sixth end 43b of heat dissipation plate 43h.

Fourth insertion port 43i extends toward a fifth end 43a. The plurality of fourth insertion ports 43i are disposed at intervals in third direction DR3. A first insertion port 41c is inserted into fourth insertion port 43i. In this regard, the configuration of circuit device 500 is different from the configuration of circuit device 100.

Third partition plate 43 having heat dissipation plate 43h is formed by, for example, forming a sheet metal having heat dissipation plate 43h by extrusion processing, and then forming a third insertion port 43c and fourth insertion port 43i by punching processing or cutting processing.

Third partition plate 43 having heat dissipation plate 43h may be formed by forming a sheet metal having third insertion port 43c and fourth insertion port 43i into a U shape by press processing, and combining the U-shaped sheet metals. Third partition plate 43 having heat dissipation plate 43h may be formed by casting such as die casting. Third partition plate 43 having heat dissipation plate 43h may be formed by performing punching processing on a sheet metal to prepare remaining portions of heat dissipation plate 43h and third partition plate 43 as separate members, and integrating them by brazing, swaging, bonding, or the like.

Although not illustrated, a plurality of fins may be formed on heat dissipation plate 43h in order to enhance heat dissipation. The fins extend in a first direction DR1. The plurality of fins are disposed at intervals in third direction DR3. Note that third partition plate 43 having heat dissipation plate 43h on which the fins are formed is formed by performing extrusion processing along an extending direction of the fins (first direction DR1).

### (Effects of Circuit Device 500)

Hereinafter, an effect of circuit device 500 will be described.

In circuit device 500, since third partition plate 43 has heat dissipation plate 43h, a contact area between third partition plate 43 and an upper surface 30a increases. As a result, since R_{b} in Equation 1 decreases, a temperature rise of third partition plate 43 (Δt in Equation 1) decreases, and a temperature rise of entire circuit device 500 is suppressed.

In circuit device 500, since heat dissipation plate 43h faces outside air, heat generated in capacitor 10a is released from heat dissipation plate 43h via a side surface (lead wire 10ab) of capacitor 10a, heat transfer member 52, and third partition plate 43 (hereinafter referred to as “sixth heat dissipation path”). As described above, in circuit device 500, since heat can be dissipated by the first heat dissipation path, the second heat dissipation path, and the sixth heat dissipation path, it is possible to further suppress a temperature rise of capacitor 10a accompanying an operation of circuit device 500. In a case where the fins are formed on heat dissipation plate 43h, cooling efficiency of heat dissipation plate 43h is improved, so that heat dissipation from the sixth heat dissipation path can be further improved.

### Sixth Embodiment

A circuit device (hereinafter referred to as “circuit device 600”) according to a sixth embodiment will be described. Hereinafter, differences from circuit device 100 will be mainly described, and redundant descriptions will not be repeated.

### (Configuration of Circuit Device 600)

Hereinafter, a configuration of circuit device 600 will be described.

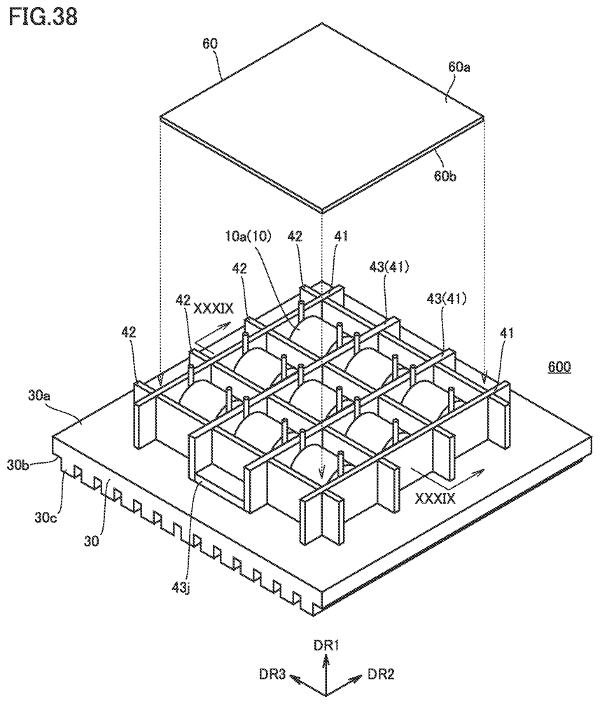

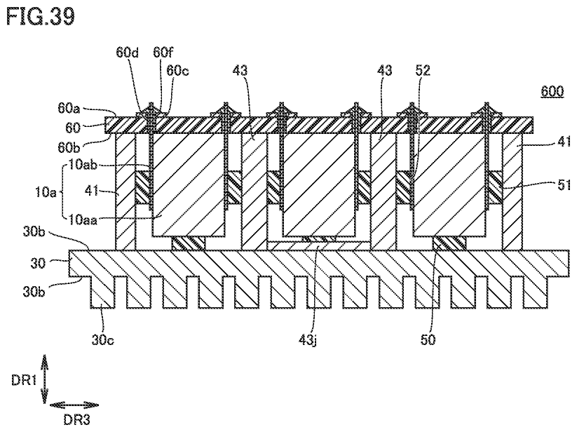

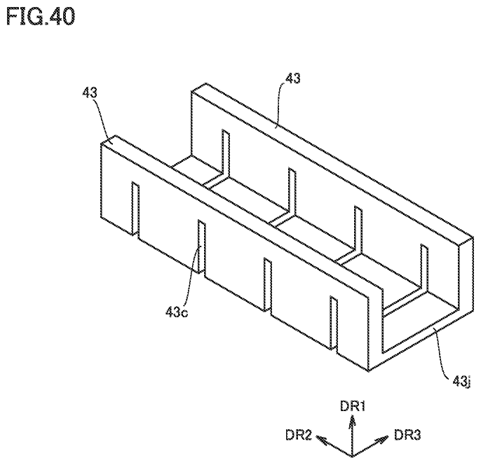

FIG. 38 is an exploded perspective view of circuit device 600. FIG. 39 is a cross-sectional view taken along line XXXIX-XXXIX in FIG. 38. FIG. 40 is a perspective view of a third partition plate 43 included in circuit device 600. As illustrated in FIGS. 38 to 40, circuit device 600 has a circuit component 10 (capacitor 10a), a heat sink 30, a plurality of first partition plates 41, and a plurality of second partition plates 42. Circuit device 600 further has an adhesive 50, a heat transfer member 51, a heat transfer member 52, and a substrate 60. First partition plate 41 at a position other than both ends in a third direction DR3 is third partition plate 43. In this regard, the configuration of circuit device 600 is in common with the configuration of circuit device 100.

Circuit device 600 further has a bottom plate 43j. Bottom plate 43j is between two adjacent third partition plates 43, and is in contact with an upper surface 30a. In this regard, the configuration of circuit device 600 is different from the configuration of circuit device 100. Note that bottom plate 43j and the two adjacent third partition plates 43 may be a single member.

The two third partition plates 43 integrated by bottom plate 43j are formed by, for example, performing punching processing on a sheet metal to form a third insertion port 43c, and then performing press processing. The two third partition plates 43 integrated by bottom plate 43j may be formed by performing punching processing or cutting processing to form third insertion port 43c after press processing. The two third partition plates 43 integrated by bottom plate 43j may be formed by casting such as die casting. The two third partition plates 43 integrated by bottom plate 43j may be formed by separately forming bottom plate 43j and the two third partition plates 43, and integrating them by brazing, swaging, bonding, or the like.

### (Effects of Circuit Device 600)

Hereinafter, an effect of circuit device 600 will be described.

In circuit device 600, since third partition plate 43 has bottom plate 43j, a contact area between third partition plate 43 and upper surface 30a increases. As a result, since R_{b} in Equation 1 decreases, a temperature rise of third partition plate 43 (Δt in Equation 1) decreases, and a temperature rise of entire circuit device 600 is suppressed. Further, in circuit device 600, a temperature rise of third partition plate 43 can be further suppressed, so that a temperature gradient between capacitor 10a between first partition plate 41 and third partition plate 43 adjacent to each other and capacitor 10a between two adjacent third partition plates 43 can be further reduced.

Furthermore, in circuit device 600, since the two adjacent third partition plates 43 are connected to each other by bottom plate 43j, a temperature difference between the two adjacent third partition plates 43 can be reduced. Therefore, according to circuit device 600, a temperature distribution in capacitor 10a between the two adjacent third partition plates 43 can be equalized.

### Seventh Embodiment

A circuit device (hereinafter referred to as “circuit device 700”) according to a seventh embodiment will be described. Hereinafter, differences from circuit device 100 will be mainly described, and redundant descriptions will not be repeated.

### (Configuration of Circuit Device 700)

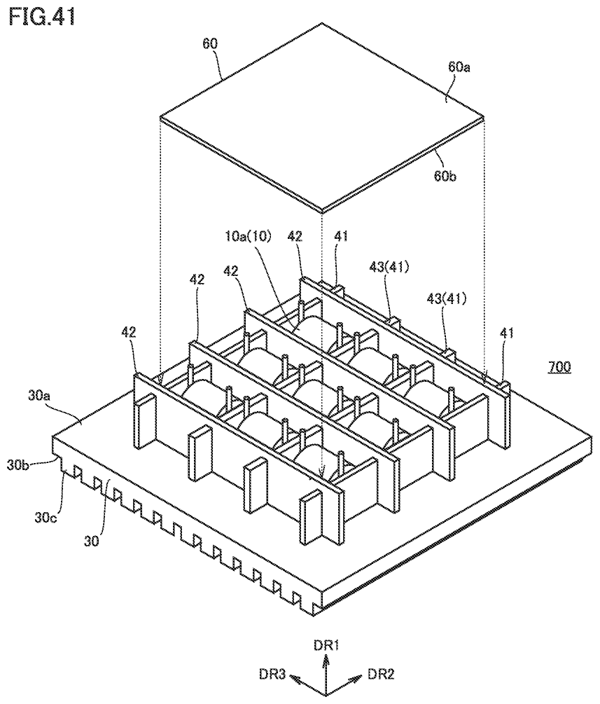

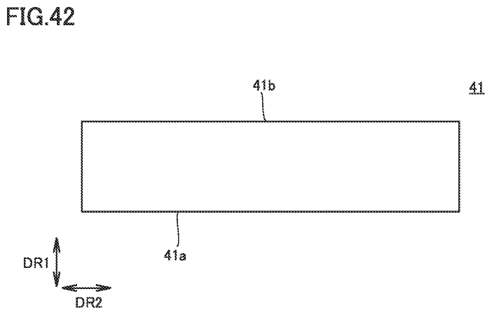

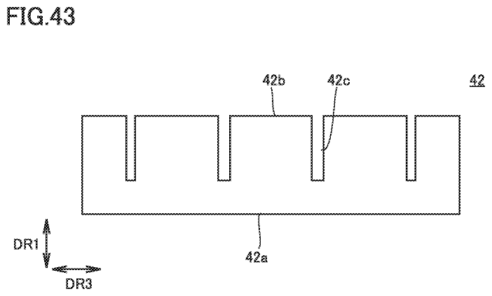

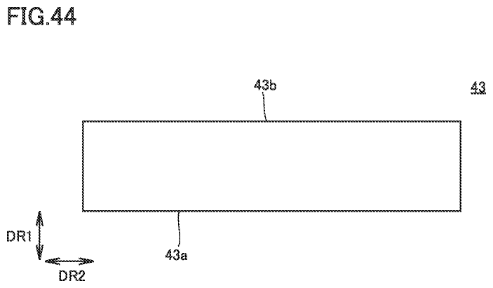

FIG. 41 is an exploded perspective view of circuit device 700. FIG. 42 is a plan view of a first partition plate 41 included in circuit device 700. FIG. 43 is a plan view of a second partition plate 42 included in circuit device 700. FIG. 44 is a plan view of a third partition plate 43 included in circuit device 700. As illustrated in FIGS. 41 to 44, circuit device 700 has a circuit component 10 (capacitor 10a), a heat sink 30, a plurality of first partition plates 41, a plurality of second partition plates 42, an adhesive 50, a heat transfer member 51, a heat transfer member 52, and a substrate 60. First partition plate 41 at a position other than both ends in a third direction DR3 is third partition plate 43. In this regard, the configuration of circuit device 700 is in common with the configuration of circuit device 100.

In circuit device 700, a first insertion port 41c is not formed in first partition plate 41, and a third insertion port 43c is not formed in third partition plate 43. In circuit device 700, second partition plate 42 has a plurality of second insertion ports 42k formed at intervals in a third direction DR3. Second insertion port 42k extends from a third end 42a toward a fourth end 42b. Second insertion port 42k penetrates second partition plate 42 along a thickness direction. Second insertion port 42k is inserted into first partition plate 41 and third partition plate 43. In this regard, the configuration of circuit device 700 is different from the configuration of circuit device 100.

### (Effects of Circuit Device 700)

Hereinafter, an effect of circuit device 700 will be described.

In circuit device 700, first insertion port 41c is not formed in first partition plate 41, and third insertion port 43c is not formed in third partition plate 43. Therefore, a contact area between first partition plate 41 and an upper surface 30a and a contact area between third partition plate 43 and upper surface 30a are increased. As a result, contact thermal resistance between first partition plate 41 and upper surface 30a and contact thermal resistance between third partition plate 43 and upper surface 30a are reduced, and a temperature rise of entire circuit device 700 is suppressed.

Further, in circuit device 700, first insertion port 41c is not formed in first partition plate 41, and third insertion port 43c is not formed in third partition plate 43. Therefore, second partition plate 42 can be moved in a second direction DR2, and the number of second partition plates 42 to be used can be increased or decreased. As a result, according to circuit device 700, even in a case of manufacturing circuit devices 700 in which capacitors 10a have different sizes or numbers of pieces to be used, it is not necessary to change shapes of first partition plate 41, second partition plate 42, and third partition plate 43, and it is possible to eliminate the need to design first partition plate 41, second partition plate 42, and third partition plate 43 according to the number of pieces to be used or size of capacitors 10a.

### Modification 1

Circuit device 700 (hereinafter referred to as “circuit device 700A”) according to Modification 1 will be described.

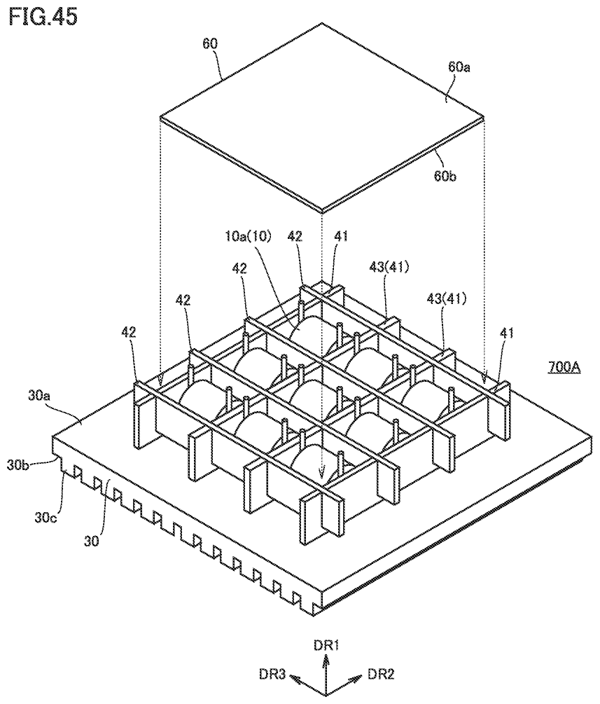

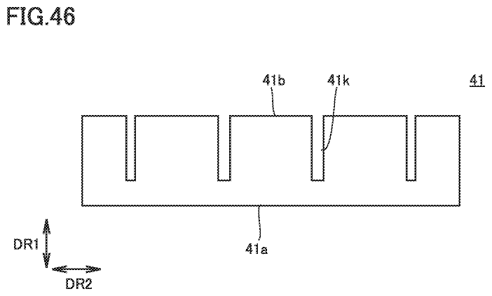

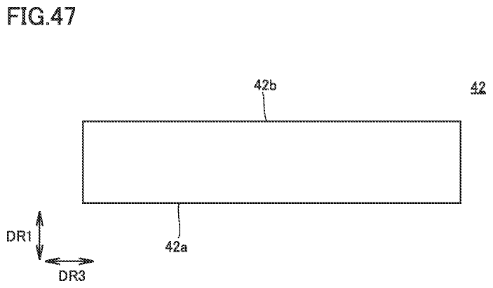

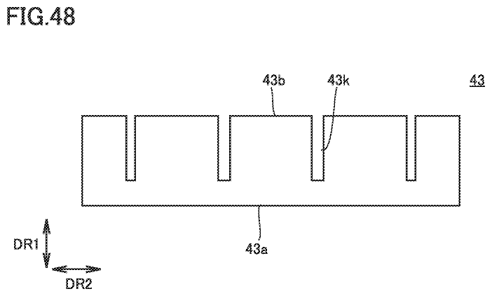

FIG. 45 is an exploded perspective view of circuit device 700A. FIG. 46 is a plan view of first partition plate 41 included in circuit device 700A. FIG. 47 is a plan view of second partition plate 42 included in circuit device 700A. FIG. 48 is a plan view of third partition plate 43 included in circuit device 700A. As illustrated in FIGS. 45 to 48, in circuit device 700A, first partition plate 41 has a plurality of first insertion ports 41k formed at intervals in second direction DR2. First insertion port 41k extends from a second end 41b toward a first end 41a. First insertion port 41k penetrates first partition plate 41 along a thickness direction.

In circuit device 700A, third partition plate 43 has a plurality of third insertion ports 43k formed at intervals in second direction DR2. Third insertion port 43k extends from a sixth end 43b toward a fifth end 43a. Third insertion port 43k penetrates third partition plate 43 along a thickness direction. In circuit device 700A, second insertion port 42k is not formed in second partition plate 42. Second partition plate 42 is inserted into first insertion port 41k and third insertion port 43k.

In circuit device 700A, similarly to circuit device 700, first insertion port 41c is not formed in first partition plate 41, and third insertion port 43c is not formed in third partition plate 43. Therefore, a contact area between first partition plate 41 and upper surface 30a and a contact area between third partition plate 43 and upper surface 30a are increased. As a result, contact thermal resistance between first partition plate 41 and upper surface 30a and contact thermal resistance between third partition plate 43 and upper surface 30a are reduced, and a temperature rise of entire circuit device 700A is suppressed.

Further, in circuit device 700A, second insertion port 42c is not formed in second partition plate 42. Therefore, first partition plate 41 and third partition plate 43 can be moved in third direction DR3, and the number of first partition plates 41 and third partition plates 43 to be used can be increased or decreased. As a result, according to circuit device 700A, even in a case of manufacturing circuit devices 700A in which capacitors 10a have different sizes or numbers of pieces to be used, it is not necessary to change shapes of first partition plate 41, second partition plate 42, and third partition plate 43, and it is possible to eliminate the need to design first partition plate 41, second partition plate 42, and third partition plate 43 according to the number of pieces to be used or size of capacitors 10a.

### Modification 2

Circuit device 700 (hereinafter referred to as “circuit device 700B”) according to Modification 2 will be described.

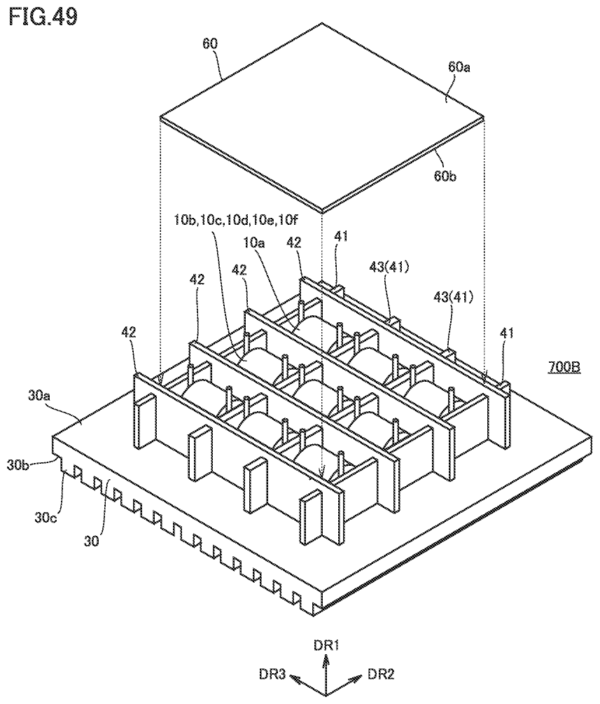

FIG. 49 is an exploded perspective view of circuit device 700B. As illustrated in FIG. 49, in circuit device 700B, some of the plurality of capacitors 10a are replaced with an inductor 10b, a contactor 10c, a discharge resistor 10d, a charge resistor 10e, and a voltage-dividing resistor 10f. In circuit device 700B, second partition plate 42 can be moved along second direction DR2 and the number of second partition plates 42 to be used can be increased or decreased in accordance with sizes of inductor 10b, contactor 10c, discharge resistor 10d, charge resistor 10e, and voltage-dividing resistor 10f. Therefore, according to circuit device 700B, heat dissipation of inductor 10b, contactor 10c, discharge resistor 10d, charge resistor 10e, and voltage-dividing resistor 10f can be improved.

It is to be understood that the embodiments that have been disclosed herein are not restrictive, but are illustrative in all respects. The basic scope of the present disclosure is defined not by the embodiments described above but by the claims, and it is intended to include all modifications within the meaning and scope equivalent to the claims.

### REFERENCE SIGNS LIST

10: circuit component, 20: circuit component, 10a: capacitor, 10aa: capacitor element body, 10ab: lead wire, 10ad: sealing resin, 10ae: lead wire, 10b: inductor, 10c: contactor, 10d: discharge resistor, 10e: charge resistor, 10f: voltage-dividing resistor, 20a, 20b, 20c, 20d, 20e, 20f transistor, 20g, 20h, 20i, 20j, 20k, 20l: diode, 30: heat sink, 30a: upper surface, 30b: lower surface, 30c: fin, 41: first partition plate, 41a: first end, 41b: second end, 41c: first insertion port, 41d: terminal, 41ea, 41eb: vertical wall portion, 41f screw hole, 41k: first insertion port, 42: second partition plate, 42a: third end, 42b: fourth end, 42c: second insertion port, 42d: terminal, 42ea, 42eb: vertical wall portion, 42f screw hole, 42k: second insertion port, 43: third partition plate, 43a: fifth end, 43b: sixth end, 43c: third insertion port, 43d: terminal, 43ea, 43eb: vertical wall portion, 43f screw hole, 43g: support portion, 43h: heat dissipation plate, 43i: fourth insertion port, 43j: bottom plate, 43k: third insertion port, 50: adhesive, 51, 52: heat transfer member, 53: sealing member, 60: substrate, 60a: first main surface, 60b: second main surface, 60c: circuit pattern, 60d: through hole, 60e: conductor film, 60f connection member, 60ga, 60gb, 60gc: penetration hole, 70: screw, 100, 100A, 100B, 100C, 100D, 200, 200A, 200B, 300, 400, 400A, 500, 600, 700, 700A, 700B: circuit device, 110: peripheral circuit, 120: switching circuit, 130: DC supply circuit, 140: motor, 141: input line, 142, 143: input line, DR1: first direction, DR2: second direction, DR3: third direction, Sb: capacitor attaching step, S2: partition plate attaching step, S3: adhesive applying step, S4: capacitor housing step, S5: screwing step

1. A circuit device comprising:
a heat sink having an upper surface orthogonal to a first direction;
a plurality of first partition plates provided at the upper surface and extending in a second direction orthogonal to the first direction;
a plurality of second partition plates provided at the upper surface and extending in a third direction orthogonal to the first direction and the second direction;
a circuit component;
a substrate electrically connected to the circuit component; and
a first heat transfer member, wherein
the circuit component is housed in a space surrounded by two adjacent first partition plates among the first partition plates, two adjacent second partition plates among the second partition plates, and the upper surface, and
the first heat transfer member is disposed between each of the first partition plates and the circuit component.

2. The circuit device according to claim 1, wherein
one of each of the first partition plates or each of the second partition plates is formed with a plurality of insertion ports disposed at intervals in an extending direction of the one of each of the first partition plates or each of the second partition plates, and
another one of each of the first partition plates or each of the second partition plates is inserted into the insertion ports.

3. The circuit device according to claim 1, wherein
in each of the plurality of first partition plates, a plurality of first insertion ports disposed at intervals in the second direction are formed,
in each of the plurality of second partition plates, a plurality of second insertion ports disposed at intervals in the third direction are formed, and
the second insertion ports are inserted into the first insertion ports.

4. The circuit device according to claim 3, wherein
at least one of the first partition plates disposed at a position other than both ends in the third direction is a third partition plate, and
a contact area between the third partition plate and the upper surface is larger than a contact area between each of the first partition plates and the upper surface.

5. The circuit device according to claim 4, wherein
in the third partition plate, a plurality of third insertion ports disposed at intervals in the second direction are formed, and
the second insertion ports are inserted into the first insertion ports and the third insertion ports.

6. The circuit device according to claim 4, wherein a thickness of the third partition plate in the third direction is larger than a thickness of each of the first partition plates in the third direction.

7. The circuit device according to claim 4, wherein the third partition plate extends in a zigzag shape in the second direction when viewed from the first direction.

8. The circuit device according tom claim 4, wherein the third partition plate has a support portion in contact with the upper surface.

9. The circuit device according to claim 4, wherein the third partition plate has a heat dissipation plate in contact with the upper surface, at both ends in the second direction.

10. The circuit device according to claim 4, further comprising a bottom plate, wherein
a number of the third partition plates is plural, and
the bottom plate is disposed between two adjacent third partition plates among the third partition plates so as to be in contact with the upper surface.

11. The circuit device according to claim 1, further comprising an adhesive, wherein
the circuit component has a top surface facing the upper surface, and
the adhesive is disposed between the top surface and the upper surface.

12. The circuit device according to claim 1, wherein
the circuit component has a circuit component body and a lead wire, and
the first heat transfer member is disposed at least one of: between each of the first partition plates and a surface of the circuit component body to which the lead wire is attached;
or between each of the first partition plates and the lead wire.

13. The circuit device according to claim 4, further comprising a second heat transfer member, wherein
the circuit component has a circuit component body and a lead wire, and
the second heat transfer member is disposed at least one of: between the third partition plate and a surface of the circuit component body to which the lead wire is attached; or between the third partition plate and the lead wire.

14. The circuit device according to claim 12, wherein
the circuit component is a capacitor, and
the circuit component body is a capacitor element body.

15. The circuit device according to claim 1, further comprising a sealing member, wherein
the sealing member seals the circuit component by filling a space surrounded by two adjacent first partition plates among the first partition plates, two adjacent second partition plates among the second partition plates, and the upper surface.

16. The circuit device according to claim 1, wherein
at least one of each of the first partition plates or each of the second partition plates has a terminal,
a through hole penetrating the substrate along a thickness direction is formed in the substrate, and
the substrate is fixed by the terminal being inserted into the through hole.

17. The circuit device according to claim 1, wherein
a screw is included,
a screw hole is formed in at least one of each of the first partition plates or each of the second partition plates,
a penetration hole is formed in the substrate, and
the substrate is fixed by the screw being passed through the penetration hole and screwed into the screw hole.

18. The circuit device according to claim 1, wherein
the first partition plates each have a first end that is an end on a side of the upper surface and a second end that is an end on a side opposite to the first end,
the second partition plates each have a third end that is an end on a side of the upper surface and a fourth end that is an end on a side opposite to the third end, and
the substrate has a first main surface and a second main surface that is a surface opposite to the first main surface, and the second main surface is disposed so as to be in contact with at least one of the second end or the fourth end.
